(19) United States
(12) Patent Application Publication
(10) Pub. No.: US 2022/0185948 A1
(43) Pub. Date: Jun. 16, 2022

(54) EPOXY RESIN, RESIN COMPOSITION, RESIN SHEET, RESIN CURED PRODUCT, RESIN SUBSTRATE AND MULTILAYER SUBSTRATE

(71) Applicant: TDK CORPORATION, Tokyo (JP)

(72) Inventors: Takashi INAGAKI, Tokyo (JP); Ayano SATO, Tokyo (JP)

(73) Assignee: TDK CORPORATION, Tokyo (JP)

(21) Appl. No.: 17/598,347

(22) PCT Filed: Mar. 24, 2020
(86) PCT No.: PCT/JP2020/012943

§ 371 Date: Sep. 27, 2021

(30) Foreign Application Priority Data
Mar. 29, 2019 (JP) 2019-068680

(51) Int. Cl. C08G 59/24; C08J 5/18; B32B 27/08; B32B 27/38; H05K 7/20

(52) U.S. Cl. CPC C08G 59/245; C08J 5/18; C08J 2363/02; B32B 27/38; H05K 7/2039; B32B 27/08

(57) ABSTRACT

An epoxy resin having end groups each having an epoxy group that are disposed at both ends respectively, and between the end groups, either or both of a first structure in which an aromatic cyclic group, an ether oxygen, a methylene group, an aromatic cyclic group, a methylene group, an ether oxygen and an aromatic cyclic group are bonded together in this order and a second structure in which an aromatic cyclic group, a methylene group, an ether oxygen, an aromatic cyclic group, an ether oxygen, a methylene group and an aromatic cyclic group are bonded together in this order.

### TECHNICAL FIELD

The present disclosure relates to an epoxy resin, a resin composition, a resin sheet, a resin cured product, a resin substrate and a multilayer substrate.

Priority is claimed on Japanese Patent Application No. 2019-068680, filed in Japan on Mar. 29, 2019, the content of which is incorporated herein by reference.

### BACKGROUND ART

Recently, in association with demand for a reduction in the size of electronic devices, the functional enhancement or high-density mounting of components has been underway. Therefore, treatment for heat that is generated from electronic components and the like has become important.

Heat generated from electronic components and the like is dissipated to the outside mainly through a substrate in a case where no special cooling mechanism is provided. Multilayer substrates for power supplies in which resin substrates are laminated are required to have particularly favorable heat dissipation properties. Therefore, inorganic particles of alumina, boron nitride, magnesium oxide or the like are added to resins, thereby enhancing the thennally conductive properties of resin substrates. For example, Patent Document 1 describes an epoxy resin composition containing an epoxy resin, a curing agent and an inorganic filler.

However, when the amount of inorganic particles in a resin is increased in order to improve the thermal conductivity, a problem with process applicability at the time of forming substrates is caused. Therefore, development of resins from which cured products having a high thermal conductivity can be obtained is underway so that substrates having high heat dissipation properties can be obtained even when process applicability is ensured by suppressing the amount of inorganic particles in the resins.

As resins having a high thermal conductivity, there is an epoxy resin into which a mesogenic skeleton has been introduced (for example, refer to Non-Patent Document 1).

In addition, Patent Document 2 discloses a mixture of an epoxy resin that can be obtained by reacting an epoxy resin that is at least bifunctional and a biphenol compound.

Patent Document 3 discloses a resin composition containing a filler and a thermosetting resin having a mesogenic group in the molecule.

### CITATION LIST

### Patent Literature

### Patent Document 1

Japanese Patent No. 6074447

### Patent Document 2

Japanese Unexamined Patent Application, First Publication No. 2012-131992

### Patent Document 3

International Publication WO 2013/065159

### Non-Patent Document 1

Yoshitaka Takezawa, POLYMERS Vol. 65 No. 2, pp. 65 to 67, 2016

### SUMMARY OF THE INVENTION

### Technical Problem

However, it has not been possible to obtain cured products having a sufficiently high thermal conductivity from conventional epoxy resins, and there has been a demand for increasing the thermal conductivity of cured products.

The present disclosure has been made in consideration of the above-described problem, and an objective of the present invention is to provide an epoxy resin from which a cured product having a high thermal conductivity can be obtained.

In addition, another objective of the present disclosure is to provide a resin composition containing the epoxy resin of the present disclosure, a resin sheet, a resin cured product, a resin substrate and a multilayer substrate.

### Solution to Problem

In order to solve the above-described problem, the present inventors paid attention to skeletons and end groups of epoxy resins and repeated intensive studies.

As a result, the present inventors found that an epoxy resin that has a structure in which an aromatic cyclic group that may have a substituent, an ether oxygen and a methylene group are bonded together in a specific order and that has end groups each having an epoxy group that bond to both ends respectively, is preferable.

That is, the present disclosure relates to the following inventions.

[1] An epoxy resin having,

end groups each having an epoxy group that are disposed at both ends respectively, and

between the end groups, either or both of

a first structure in which an aromatic cyclic group, an ether oxygen, a methylene group, an aromatic cyclic group, a methylene group, an ether oxygen and an aromatic cyclic group are bonded together in this order and

a second structure in which an aromatic cyclic group, a methylene group, an ether oxygen, an aromatic cyclic group, an ether oxygen, a methylene group and an aromatic cyclic group are bonded together in this order.

[2] The epoxy resin according to [1], including

a first aromatic cyclic unit composed of a first aromatic cyclic group and two ether oxygens bonding to the first aromatic cyclic group,

a second aromatic cyclic unit composed of a second aromatic cyclic group and two methylene groups bonding to the second aromatic cyclic group and

a third aromatic cyclic unit composed of a third aromatic cyclic group and an end group having an epoxy group that bonds to the third aromatic cyclic group,

in which the epoxy resin includes a skeleton in which the first aromatic cyclic units and the second aromatic cyclic units are alternately disposed, and

the first aromatic cyclic units are disposed at both ends of the skeleton and bonded to the third aromatic cyclic groups via methylene groups, or

the second aromatic cyclic units are disposed at both ends of the skeleton and bonded to the third aromatic cyclic groups via ether oxygens.

[3] The epoxy resin according to [1] that is represented by General Formula (1) below or General Formula (2) below.

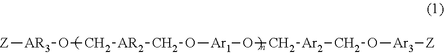

(In Formula (1), Ar₁ each independently represents a first aromatic cyclic group that may have a substituent, Ar₂ each independently represents a second aromatic cyclic group that may have a substituent, and Ar₃ each independently represents a third aromatic cyclic group that may have a substituent; Z each independently represents an end group having an epoxy group; and n is an integer of 0 or larger.)

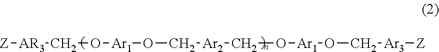

(In Formula (2), Ar₁ each independently represents a first aromatic cyclic group that may have a substituent, Ar₂ each independently represents a second aromatic cyclic group that may have a substituent, and Ar₃ each independently represents a third aromatic cyclic group that may have a substituent; Z each independently represents an end group having an epoxy group; and n is an integer of 0 or larger.)

[4] The epoxy resin according to [2] or [3], in which one or more of the first aromatic cyclic group, the second aromatic cyclic group and the third aromatic cyclic group are a para-phenylene group that may have a substituent.

[5] The epoxy resin according to any one of [2] to [4], in which the first aromatic cyclic group and the third aromatic cyclic group are identical to each other, and the second aromatic cyclic group is a para-phenylene group.

[6] The epoxy resin according to any one of [1] to [5] that is represented by General Formula (9) below.

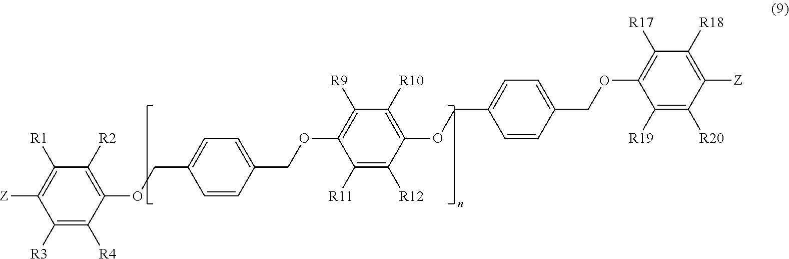

(In Formula (9), R1 to R4, R9 to R12 and R17 to R20 are each independently any one selected from the group consisting of hydrogen, a methyl group, a trifluoromethyl group, a halogen group and a nitro group; Z each independently represents an end group having an epoxy group; and n is an integer of 0 or larger.)

[7] The epoxy resin according to [6], in which any one of the R1 to the R4 is a methyl group and the others are hydrogen, any one of the R9 to the R12 is a methyl group and others are hydrogen, and any one of the R17 to the R20 is a methyl group and the others are hydrogen.

[8] The epoxy resin according to [3] or [6], in which then is an integer of 0 to 10.

[9] The epoxy resin according to any one of [1] to [8], in which the end group having an epoxy group is a group in which an epoxy group is bonded to a linking group having one or more of a methylene group, an ether bond, an ester bond, a ketone group and an amide bond.

[10] The epoxy resin according to any one of [1] to [9], in which the end group having an epoxy group is any one of Formulae (3) to (8) below.

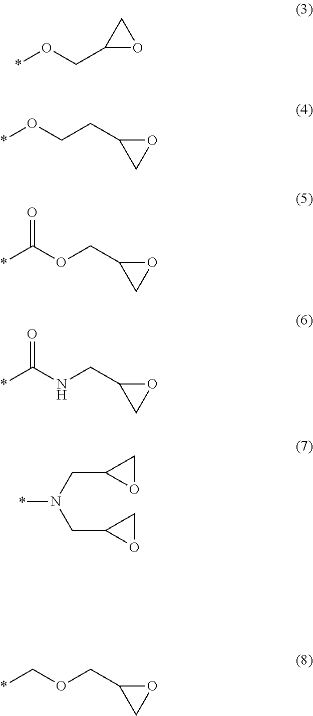

[11] A resin composition containing the epoxy resin according to any one of [1] to [10].

[12] A resin sheet that is obtained by forming the resin composition according to [11].

[13] A resin cured product containing a cured product of the resin composition according to [11].

[14] A resin substrate containing a cured product of the resin composition according to [11].

[15] A multilayer substrate in which a plurality of resin substrates is laminated, and at least one of the plurality of resin substrates includes a cured product of the resin composition according to [11].

### Advantageous Effects of Invention

The epoxy resin of the present disclosure has, between the end groups each having an epoxy group that are disposed at both ends respectively, either or both of the first structure in which an aromatic cyclic group, an ether oxygen, a methylene group, an aromatic cyclic group, a methylene group, an ether oxygen and an aromatic cyclic group are bonded together in this order and/or the second structure in which an aromatic cyclic group, a methylene group, an ether oxygen, an aromatic cyclic group, an ether oxygen, a methylene group and an aromatic cyclic group are bonded together in this order. The first structure and the second structure each have a structure in which aromatic cyclic groups that are each a mesogenic group developing liquid crystallinity and impart rigidity, methylene groups and ether oxygens that impart mobility are disposed in a specific order. Due to this fact, the epoxy resin of the present disclosure is capable of stabilizing a smectic liquid crystal phase with appropriate mobility intrinsic to the mesogenic groups in spite of having no long side chains which are typically observable in liquid crystal molecules. Therefore, the epoxy resin of the present disclosure has high orientation, and a cured product which has a smectic liquid crystal structure and is highly thermally conductive due to suppression of the scattering of phonons can be obtained by curing the epoxy resin of the present disclosure.

### BRIEF DESCRIPTION OF DRAWINGS

FIG. 1 is a schematic perspective view showing an example of a resin sheet and a resin substrate.

FIG. 2 is a schematic cross-sectional view taken along a line II-II of the resin sheet and the resin substrate in FIG. 1.

FIG. 3 is a schematic perspective view of a multilayer substrate.

FIG. 4 is a schematic cross-sectional view taken along a line IV-IV of the multilayer substrate in FIG. 3.

### DESCRIPTION OF EMBODIMENTS

Hereinafter, preferable examples of the present disclosure will be described in detail with appropriate reference to the drawings. In the drawings to be used in the following description, there are cases where a characteristic portion is shown in an enlarged manner for convenience in order to facilitate the understanding of the characteristics of the present disclosure. Therefore, the dimensional ratios and the like of each configuration element shown in the drawings are different from actual ones in some cases. The material, dimensions, and the like in the following description are simply exemplary examples, and the present disclosure is not limited thereto and can be appropriately modified and carried out within the scope of the gist of the present invention.

### “Epoxy Resin”

An epoxy resin of the present embodiment has a first structure and/or a second structure between end groups each having an epoxy group that are disposed at both ends respectively.

The first structure is a structure in which an aromatic cyclic group, an ether oxygen, a methylene group, an aromatic cyclic group, a methylene group, an ether oxygen and an aromatic cyclic group are bonded together in this order.

The second structure is a structure in which an aromatic cyclic group, a methylene group, an ether oxygen, an aromatic cyclic group, an ether oxygen, a methylene group and an aromatic cyclic group are bonded together in this order.

The epoxy resin of the present embodiment preferably includes a first aromatic cyclic unit, a second aromatic cyclic unit and a third aromatic cyclic unit, all of which will be described below.

The first aromatic cyclic unit is composed of a first aromatic cyclic group and two ether oxygens bonding to the first aromatic cyclic group.

The second aromatic cyclic unit is composed of a second aromatic cyclic group and two methylene groups bonding to the second aromatic cyclic group.

The third aromatic cyclic unit is composed of a third aromatic cyclic group and an end group having an epoxy group that bonds to the third aromatic cyclic group.

The epoxy resin of the present embodiment preferably includes a skeleton in which the first aromatic cyclic units and the second aromatic cyclic units are alternately disposed one or more times.

At both ends of the skeleton, the first aromatic cyclic units may be disposed or the second aromatic cyclic units may be disposed. When either the first aromatic cyclic units or the second aromatic cyclic units is disposed at both ends of the skeleton, the skeleton is preferably provided with a symmetric structure.

In the epoxy resin of the present embodiment, in a case where the first aromatic cyclic units are disposed at both ends of the skeleton, the first aromatic cyclic units are bonded to the third aromatic cyclic groups with the methylene groups. In addition, in the epoxy resin of the present embodiment, in a case where the second aromatic cyclic units are disposed at both ends of the skeleton, the second aromatic cyclic units are bonded to the third aromatic cyclic groups with the ether oxygens.

All of the first aromatic cyclic group, the second aromatic cyclic group and the third aromatic cyclic group in the epoxy resin of the present embodiment may be an aromatic cyclic group and may have a substituent. The expression “the aromatic cyclic group may have a substituent” may mean that the aromatic cyclic group has a substituent or has no substituent. The first aromatic cyclic group, the second aromatic cyclic group and the third aromatic cyclic group may be different from one another and may be partially or entirely identical to one another, which can be appropriately determined depending on the application or the like of the epoxy resin.

In a case where the epoxy resin of the present embodiment has a plurality of the first aromatic cyclic groups, the plurality of first aromatic cyclic groups may be different from each other or may be partially or entirely identical to each other. The plurality of first aromatic cyclic groups are preferably identical to each other since the epoxy resin in which the plurality of first aromatic cyclic groups are all identical to each other can be easily produced.

In addition, in a case where the epoxy resin of the present embodiment has a plurality of the second aromatic cyclic groups, the plurality of second aromatic cyclic groups may be different from each other or may be partially or entirely identical to each other. The plurality of second aromatic cyclic groups are preferably identical to each other since the epoxy resin in which the plurality of second aromatic cyclic groups are all identical to each other can be easily produced.

In addition, the third aromatic cyclic groups that are disposed at both ends of the skeleton of the epoxy resin of the present embodiment may be different from each other or identical to each other. The third aromatic cyclic groups are preferably identical to each other since the epoxy resin in which the third aromatic cyclic groups that are disposed at both ends of the skeleton are identical to each other can be easily produced.

One or more of the first aromatic cyclic group, the second aromatic cyclic group and the third aromatic cyclic group in the epoxy resin of the present embodiment are preferably a phenylene group that may have a substituent in order to make an epoxy resin from which a cured product having a higher thermal conductivity can be obtained. The phenylene group of the phenylene group that may have a substituent may be any of an ortho-phenylene group, a meta-phenylene group and a para-phenylene group. The phenylene group is particularly preferably a para-phenylene group since the epoxy resin then has a skeleton exhibiting high orientation.

In the epoxy resin of the present embodiment, any one of the first aromatic cyclic group and the second aromatic cyclic group is more preferably a para-phenylene group. Such an epoxy resin is preferable since a cured product having a higher thermal conductivity can be obtained.

In the epoxy resin of the present embodiment, particularly, the second aromatic cyclic group is preferably a para-phenylene group. In such an epoxy resin, a cured product having an even higher thermal conductivity can be obtained.

In the epoxy resin of the present embodiment, the substituents in the first aromatic cyclic group, the second aromatic cyclic group and the third aromatic cyclic group are preferably any one selected from the group consisting of a methyl group, a trifluoromethyl group, a halogen group and a nitro group, can be appropriately determined depending on the application or the like of the epoxy resin, and are not particularly limited. Among these substituents, particularly, a methyl group, a trifluoromethyl group and a halogen group are preferable from the viewpoint of chemical stability and the reduction of environmental burden and a methyl group is particularly preferable.

In the epoxy resin of the present embodiment, the end group having an epoxy group bonded to the third aromatic cyclic group is preferably a group in which an epoxy group is bonded to a linking group having one or more of a methylene group, an ether bond, an ester bond, a ketone group and an amide bond and can be appropriately determined depending on the application or the like of the epoxy resin. In a case where the end group having an epoxy group bonded to the third aromatic cyclic group is a group in which an epoxy group is bonded to any of the above-described linking groups, a bonding portion between the end group having an epoxy group and the skeleton does not become too rigid, and the balance between orientation and molecular mobility becomes favorable. As a result, the epoxy resin has sufficient solubility in solvents, and a cured product having favorable thermally conductive properties can be obtained from the epoxy resin.

In the epoxy resin of the present embodiment, since the end group having an epoxy group is a group that can be easily introduced into the skeleton of the epoxy resin and an epoxy resin having more favorable thermally conductive properties can be obtained, specifically, the end group is preferably any of Formulae (3) to (8) below. The end group can be appropriately determined depending on the application or the like of the epoxy resin. The end group having an epoxy group is particularly preferably an end group indicated by Formula (3) or Formula (7) in order to produce an epoxy resin having higher thermally conductive properties. The end group having an epoxy group is preferably an end group indicated by Formula (3) since then the synthesis of an epoxy resin is easy.

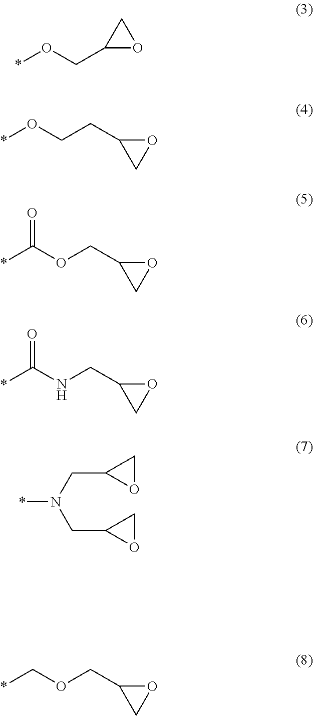

Examples of the epoxy resin of the present embodiment include epoxy resins represented by General Formula (1) below or General Formula (2) below.

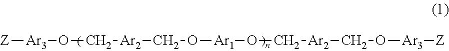

(In Formula (1), Ar₁ each independently represents the first aromatic cyclic group that may have a substituent, Ar₂ each independently represents the second aromatic cyclic group that may have a substituent, and Ar₃ each independently represents the third aromatic cyclic group that may have a substituent; Z each independently represents an end group having an epoxy group; and n is an integer of 0 or larger.)

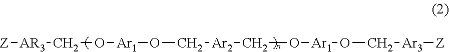

(In Formula (2), Ar₁ each independently represents the first aromatic cyclic group that may have a substituent, Ar₂ each independently represents the second aromatic cyclic group that may have a substituent, and Ar₃ each independently represents the third aromatic cyclic group that may have a substituent; Z each independently represents an end group having an epoxy group; and n is an integer of 0 or larger.)

The epoxy resins represented by General Formula (1) and Formula (2) include the first aromatic cyclic unit (indicated by —O—Ar₁—O— in Formula (1) and Formula (2)), the second aromatic cyclic unit (indicated by —CH₂—Ar₁—CH₂— in Formula (1)) and the third aromatic cyclic unit (indicated by —Ar₃—Z in Formula (1) and Formula (2)).

In the epoxy resins represented by General Formula (1) and Formula (2), the first aromatic cyclic unit has a first aromatic cyclic group (indicated by Ar₁ in Formula (1) and Formula (2)) and two ether oxygens bonding to the first aromatic cyclic group.

The second aromatic cyclic unit has a second aromatic cyclic group (indicated by Ar₂ in Formula (1) and Formula (2)) and two methylene groups bonding to the second aromatic cyclic group.

The third aromatic cyclic unit is composed of the third aromatic cyclic group indicated by Ar₃ in Formulae (1) and (2) and an end group having an epoxy group that bonds to the third aromatic cyclic group (indicated by Z in Formula (1) and Formula (2)).

All of the first aromatic cyclic group, the second aromatic cyclic group and the third aromatic cyclic group that are contained in the epoxy resin represented by General Formula (1) and Formula (2) may have a substituent.

The epoxy resin represented by General Formula (1) includes a skeleton in which the first aromatic cyclic units and the second aromatic cyclic units are alternately disposed in a chain shape and has a skeleton in which both ends are terminated with the second aromatic cyclic units. In the epoxy resin represented by General Formula (1), the methylene groups in the second aromatic cyclic unit are disposed at both ends of the skeleton, and the second aromatic cyclic unit is bonded to the third aromatic cyclic group indicated by Ar₃ in Formula (1) with the ether oxygen.

In addition, the epoxy resin represented by General Formula (2) includes a skeleton in which the first aromatic cyclic units and the second aromatic cyclic units are alternately disposed in a chain shape and has a skeleton in which both ends are terminated with the first aromatic cyclic units. In the epoxy resin represented by General Formula (2), the ether oxygens in the first aromatic cyclic unit are disposed at both ends of the skeleton, and the first aromatic cyclic unit is bonded to the third aromatic cyclic group indicated by Ar₃ in Formula (2) with the methylene group.

Therefore, both ends of the epoxy resins represented by General Formulae (1) and (2) are the end groups having an epoxy group, which are indicated by Z in Formulae (1) and (2), that bond to the third aromatic cyclic group.

Examples of an epoxy resin in which all of the first aromatic cyclic group, the second aromatic cyclic group and the third aromatic cyclic group are a para-phenylene group that may have a substituent in the epoxy resin of the present embodiment include epoxy resins represented by General Formula (10) below or General Formula (11) below.

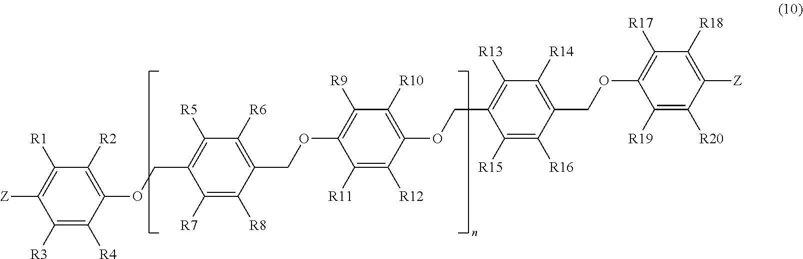

(In Formula (10), R1 to R20 are each independently any one selected from the group consisting of hydrogen, a methyl group, a trifluoromethyl group, a halogen group and a nitro group. Z is an end group having an epoxy group. n is an integer of 0 or larger.)

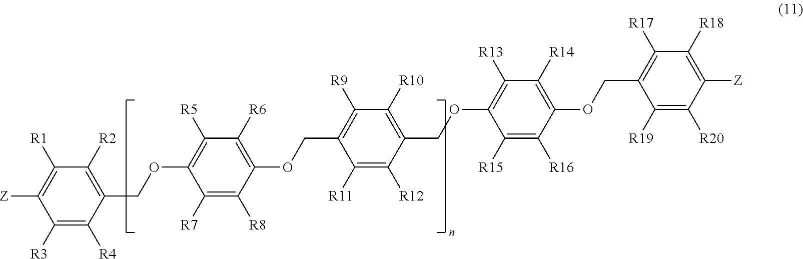

(In Formula (11), R1 to R20 are each independently any one selected from the group consisting of hydrogen, a methyl group, a trifluoromethyl group, a halogen group and a nitro group. Z is an end group having an epoxy group. n is an integer of 0 or larger.)

The epoxy resins represented by General Formula (10) and General Formula (11) have the first aromatic cyclic unit composed of a para-phenylene group that may have a substituent as the first aromatic cyclic group and two ether oxygens disposed at para positions with respect to the first aromatic cyclic group. In addition, the epoxy resins have the second aromatic cyclic unit composed of a para-phenylene group that may have a substituent as the second aromatic cyclic group and two methylene groups disposed at para positions with respect to the first aromatic cyclic group. Furthermore, the epoxy resins have the third aromatic cyclic unit composed of a para-phenylene group that may have a substituent as the third aromatic cyclic group and end groups having an epoxy group (indicated by Z in Formulae (10) and (11)).

The epoxy resin represented by General Formula (10) has a skeleton in which the first aromatic cyclic units and the second aromatic cyclic units are alternately disposed and both ends are terminated with the second aromatic cyclic units. Furthermore, the end group having an epoxy group and the ether oxygen bonded to the skeleton are disposed at para positions with respect to the para-phenylene group that may have a substituent as the third aromatic cyclic group, and the third aromatic cyclic units are disposed symmetrically with respect to the skeleton. Due to these facts, the skeleton of the epoxy resin represented by General Formula (10) exhibits liquid crystallinity and exhibits high orientation. Therefore, a cured product having more favorable thermally conductive properties can be obtained from the epoxy resin represented by General Formula (10).

In addition, the epoxy resin represented by General Formula (11) has a skeleton in which the first aromatic cyclic units and the second aromatic cyclic units are alternately disposed and both ends are terminated with the first aromatic cyclic units. Furthermore, the end group having an epoxy group and the methylene group bonded to the skeleton are disposed at para positions with respect to the para-phenylene group that may have a substituent as the third aromatic cyclic group, and the third aromatic cyclic units are disposed symmetrically with respect to the skeleton. Due to these facts, the skeleton of the epoxy resin represented by General Formula (11) exhibits liquid crystallinity and exhibits high orientation. Therefore, a cured product having more favorable thermally conductive properties can be obtained from the epoxy resin represented by General Formula (11).

Examples of an epoxy resin in which the first aromatic cyclic group and the third aromatic cyclic group are a para-phenylene group that may have a substituent and the second aromatic cyclic group is a para-phenylene group in the epoxy resin of the present embodiment include an epoxy resin represented by General Formula (9) below.

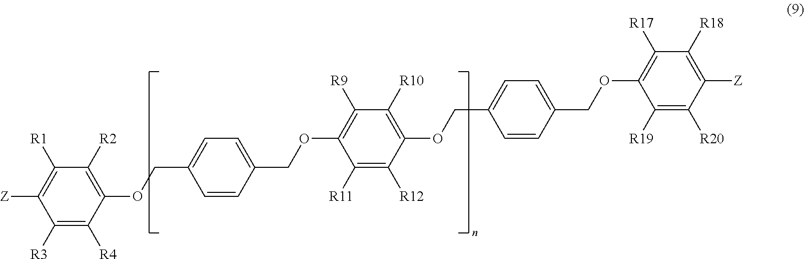

(In Formula (9), R1 to R4, R9 to R12 and R17 to R20 are each independently any one selected from the group consisting of hydrogen, a methyl group, a trifluoromethyl group, a halogen group and a nitro group. Z each independently represents an end group having an epoxy group. n is an integer of 0 or larger.)

In the epoxy resin represented by General Formula (9), the first aromatic cyclic group and the third aromatic cyclic group are the para-phenylene group that may have a substituent, and the second aromatic cyclic group is a para-phenylene group. Therefore, the epoxy resin represented by General Formula (9) has a skeleton in which the methylene groups bond to both sides of the para-phenylene group and exhibit higher orientation. Therefore, according to the epoxy resin represented by General Formula (9), a cured product having more favorable thermally conductive properties can be obtained. In addition, in the epoxy resin represented by General Formula (9), since the second aromatic cyclic group is a para-phenylene group having no substituent, procurement of a raw material is easy.

In the epoxy resin represented by General Formula (9), the end group having an epoxy group and the ether oxygen bonded to the skeleton are disposed at para positions with respect to the para-phenylene group that may have a substituent as the third aromatic cyclic group. Therefore, in the epoxy resin represented by General Formula (9), compared with, for example, a case where the end group having an epoxy group and the methylene group bonded to the skeleton are disposed at para positions with respect to the para-phenylene group that may have a substituent as the third aromatic cyclic group, the bonding portion between the end group having an epoxy group and the skeleton does not become too rigid, and the balance between orientation and molecular mobility becomes favorable. As a result, the epoxy resin represented by General Formula (9) has sufficient solubility in solvents, and a cured product having favorable thermally conductive properties can be obtained from the epoxy resin.

In the epoxy resins represented by General Formula (1), Formula (2) and Formula (9) to Formula (11), Z each independently represents an end group having an epoxy group, preferably a group in which an epoxy group is bonded to a linking group having one or more of a methylene group, an ether bond, an ester bond, a ketone group and an amide bond, and more preferably any of Formulae (3) to (8). In the epoxy resins represented by General Formula (1), Formula (2) and Formula (9) to Formula (11), when Z is any of Formulae (3) to (8), the epoxy resin has more favorable thermally conductive properties. Furthermore, since all of the groups indicated by Formulae (3) to (8) can be easily introduced into the skeleton of the epoxy resin, when Z is any of Formulae (3) to (8), the epoxy resin can be easily produced.

Particularly, in the epoxy resin represented by General Formula (9), Z is preferably the end group indicated by Formula (3). In such an epoxy resin, the third aromatic cyclic group, which is a para-phenylene group that may have a substituent, and the end group having an epoxy group that is indicated by Formula (3), which bonds to the third aromatic cyclic group, are bonded to both ends of the skeleton. Therefore, the third aromatic cyclic group and the end group having an epoxy group do not impair the formation of a smectic liquid crystal phase in the epoxy resin, and a cured product having favorable thermally conductive properties can be obtained from the epoxy resin.

In the epoxy resins represented by General Formula (1), Formula (2) and Formula (9) to Formula (11), n is the number of repeating units written in a parenthesis. In the epoxy resins represented by General Formula (1), Formula (2) and Formula (9) to Formula (11), n is an integer of 0 or larger. n in Formula (1), Formula (2) and Formula (9) to Formula (11) is 0 or larger such that an effect of having the above-described skeleton that improves the thermal conductivity of cured products can be obtained and n is preferably one or larger and more preferably two or larger such that the effect of having the above-described skeleton that improves the thermal conductivity of cured products becomes more significant. In addition, the upper limit of n in Formula (1), Formula (2) and Formula (9) to Formula (11) is not particularly limited, but is preferably 10 or smaller in order to ensure the solubility of the epoxy resin in solvents and more preferably six or smaller in order to produce epoxy resins having more favorable solubility in solvents.

n can be selected as necessary. For example, n may be any one of integers indicated by 0, 1, 2, 3, 4, 5, 6, 7, 8, 9 and 10. For example, the lower limit of n may be any of integers within a range of 0 to 10, and the upper limit of n may be any of integers within a range of 0 to 10. Specifically, n may be an integer within a range of 0 to 10, an integer within a range of 0 to 9, an integer within a range of 0 to 8, an integer within a range of 0 to 6, an integer within a range of 0 to 5, an integer within a range of 0 to 4, an integer within a range of 0 to 3 or an integer within a range of 0 to 2. n may be an integer within a range of 1 to 9, an integer within a range of 1 to 8, an integer within a range of 1 to 6, an integer within a range of 1 to 5, an integer within a range of 1 to 4, an integer within a range of 1 to 3 or an integer within a range of 1 to 2. n may be one. n may be an integer within a range of 2 to 9, an integer within a range of 2 to 8, an integer within a range of 2 to 6, an integer within a range of 2 to 5, an integer within a range of 2 to 4 or an integer within a range of 2 to 3.

The skeleton of the epoxy resin of the present embodiment has a repeating unit composed of one first aromatic cyclic unit and one second aromatic cyclic unit. The epoxy resin of the present embodiment may be a mixture including a plurality of kinds of epoxy resins having different numbers of repeating units or may be a single epoxy resin having the same number of repeating units.

In a case where the epoxy resin of the present embodiment is a mixture including a plurality of kinds of epoxy resins having different numbers of repeating units, the average polymerization degree, which is the average value of the numbers of repeating units of the epoxy resins in the mixture, is preferably 1.0 to 6.0 and more preferably 2.0 to 5.0. When the average polymerization degree is 1.0 or higher, a cured product having an even higher thermal conductivity can be obtained from the epoxy resin. In addition, when the average polymerization degree is 6.0 or lower, the epoxy resin becomes more favorable in solubility in solvents.

The epoxy resin of the present embodiment has the first structure or the second structure between end groups each having an epoxy group that are disposed at both ends respectively, even when n is 0 in the epoxy resins represented by General Formula (1), Formula (2) and Formula (9) to Formula (11) is zero. The first structure is a structure in which an aromatic cyclic group, an ether oxygen, a methylene group, an aromatic cyclic group, a methylene group, an ether oxygen and an aromatic cyclic group are bonded together in this order. The second structure is a structure in which an aromatic cyclic group, a methylene group, an ether oxygen, an aromatic cyclic group, an ether oxygen, a methylene group and an aromatic cyclic group are bonded together in this order. The first structure and the second structure each have a structure in which aromatic cyclic groups that are each a mesogenic group developing liquid crystallinity and impart rigidity, methylene groups and ether oxygens that impart mobility are disposed in a specific order. Due to this fact, according to the epoxy resin of the present embodiment, a cured product having high thermally conductive properties can be obtained.

In the epoxy resins represented by General Formula (9) to Formula (11), it is preferable that any one of R1 to R4 is a methyl group and others are hydrogen, any one of R9 to R12 is a methyl group and others are hydrogen, and any one of R17 to R20 is a methyl group and others are hydrogen. In other words, in the epoxy resins represented by General Formula (9) to Formula (11), the first aromatic cyclic group and the third aromatic cyclic group are preferably a para-phenylene group having one methyl group. In this case, compared with a case where all of the first aromatic cyclic group, the second aromatic cyclic group and the third aromatic cyclic group are a para-phenylene group having no substituent, crystallinity in the skeleton deteriorates, and a smectic liquid crystal phase is stabilized. As a result, a cured product having favorable thermally conductive properties can be obtained from the epoxy resin.

In the epoxy resin of the present embodiment, the first aromatic cyclic group and the third aromatic cyclic group are preferably identical to each other. When the first aromatic cyclic group and the third aromatic cyclic group are identical to each other, compared with a case where the first aromatic cyclic group and the third aromatic cyclic group are different from each other, the epoxy resin can be easily produced and becomes excellent in terms of productivity.

Particularly, in a case where the first aromatic cyclic group and the third aromatic cyclic group are identical to each other and the second aromatic cyclic group is a para-phenylene group, the epoxy resin can be easily produced and becomes excellent in terms of productivity.

In an epoxy resin of the present embodiment, the first aromatic cyclic group and the second aromatic cyclic group may be identical to each other or may be different from each other. That is, both the first aromatic cyclic group and the second aromatic cyclic group may be a para-phenylene group having no substituent. In this case, procurement of a raw material is easy, which is preferable. In addition, in a case where the first aromatic cyclic group and the second aromatic cyclic group are different from each other, compared with a case where the first aromatic cyclic group and the second aromatic cyclic group are identical to each other, the symmetry of the structure in the skeleton becomes poor. Therefore, the crystallinity of the epoxy resin deteriorates, and a smectic liquid crystal phase is stabilized. As a result, a cured product having favorable thermally conductive properties can be obtained from the epoxy resin.

Specific examples of a preferable epoxy resin of the present embodiment include epoxy resins represented by General Formula (A) and General Formula (B) and the like.

In the epoxy resin indicated by General Formula (A), the first aromatic cyclic group and the third aromatic cyclic group are a para-phenylene group having a methyl group, the second aromatic cyclic group is a para-phenylene group, the end group having an epoxy group is the end group indicated by Formula (3) and the end group having an epoxy group and an ether oxygen bonded to the skeleton are disposed at para positions with respect to the para-phenylene group that may have a substituent as the third aromatic cyclic group.

In the epoxy resin indicated by General Formula (B), the first aromatic cyclic group and the third aromatic cyclic group are a para-phenylene group having a methyl group, the second aromatic cyclic group is a para-phenylene group, the end group having an epoxy group is the end group indicated by Formula (7) and the end group having an epoxy group and an ether oxygen bonded to the skeleton are disposed at para positions with respect to the para-phenylene group that may have a substituent as the third aromatic cyclic group.

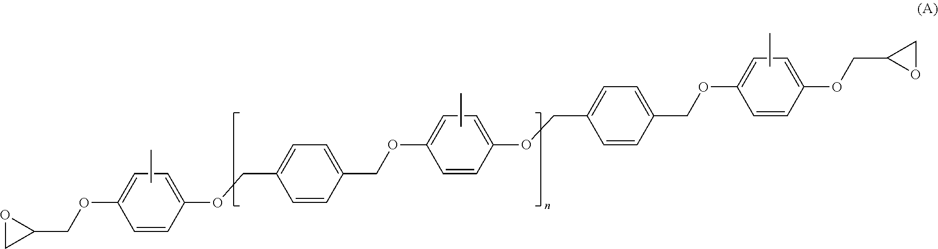

(In Formula (A), n is an integer of 0 or larger.)

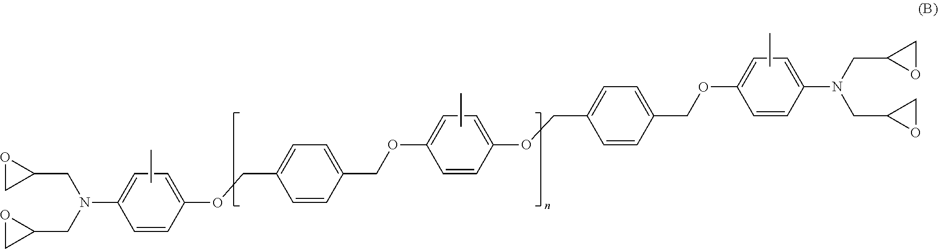

(In Formula (B), n is an integer of 0 or larger.)

### “Method for Producing Epoxy Resin”

The epoxy resin of the present embodiment can be produced by, for example, a method described below.

A first raw material that is an aromatic compound having two phenolic hydroxyl groups and a second raw material that is an aromatic compound having a monohalogenated methyl group are prepared.

In addition, a bimolecular nucleophilic substitution reaction (S_{N}2 reaction) between the first raw material and the second raw material is caused to synthesize a first precursor compound having a structure derived from the skeleton in the epoxy resin of the present embodiment. The conditions for the reaction between the first raw material and the second raw material can be appropriately determined depending on the combination of the first raw material and the second raw material and are not particularly limited.

The first raw material that is used in the method for producing the epoxy resin of the present embodiment is an aromatic compound having two phenolic hydroxyl groups and is appropriately selected depending on the structure of an epoxy resin to be produced. Examples of the first raw material include methylhydroquinone, hydroquinone, tetramethylhydroquinone, trimethylhydroquinone, 2-(trifluoromethyl)-1,4-benzenediol, fluorohydroquinone, chlorohydroquinone, bromohydroquinone, 2,5-dihydroxynitrobenzene, tetrafluorohydroquinone, tetrachlorohydroquinone, tetrabromohydroquinone, 2,6-dihydroxynaphthalene, 1,5-dihydroxynaphthalene, 4,4′-dihydroxybiphenyl, 3,3′,5,5′-tetramethylbiphenyl-4,4′-diol and the like.

The second raw material that is used in the method for producing the epoxy resin of the present embodiment is an aromatic compound having a monohalogenated methyl group and is appropriately selected depending on the structure of an epoxy resin to be produced. Examples of the second raw material include α,α′-dichloro-p-xylene, 1,4-bis(chloromethyl)-2-methylbenzene, 3,6-bis(chloromethyl)durene, 1,4-bis(bromomethyl)-2-fluorobenzene, 1,4-bis(bromomethyl)-2-chlorobenzene, 2-bromo-1,4-bis(bromomethyl)benzene, 1,4-bis(chloromethyl)-2-nitrobenzene, 1,4-bis(bromomethyl)-2,3,5,6-tetrafluorobenzene, α,α′,2,3,5,6-hexachloro-p-xylene, 1,2,4,5-tetrabromo-3,6-bis(bromomethyl)benzene, 1,2-dibromo-3,6-bis(chloromethyl)-4,5-dimethylbenzene, 1,4-bis(bromomethyl)-2,5-dimethylbenzene, 4,4′-bis(chloromethyl)biphenyl, 2,6-bis(bromomethyl)naphthalene, 1,5-bis(chloromethyl)naphthalene and the like.

Next, the obtained first precursor compound and a third raw material are reacted with each other to synthesize a second precursor compound. The conditions for the reaction between the first precursor compound and the third raw material can be appropriately determined depending on the combination of the first precursor compound and the third raw material and are not particularly limited.

The third raw material that is used in the method for producing the epoxy resin of the present embodiment is appropriately selected depending on the structure of an end group having an epoxy group, the structure of a third aromatic cyclic group and the like in an epoxy resin to be produced. In addition, as the third raw material, different raw materials are used in a case where elements disposed at both ends of the skeleton of the previously-synthesized first precursor compound have a structure derived from the first raw material and a case where the elements have a structure derived from the second raw material, respectively.

In a case where the elements disposed at both ends of the skeleton of the first precursor compound have a structure derived from the first raw material, as the third raw material, similar to the second raw material, an aromatic compound having a monohalogenated methyl group is used. Specific examples thereof include α,α′-dichloro-p-xylene, 1,4-bis(chloromethyl)-2-methylbenzene, 3,6-bis(chloromethyl)durene, 1,4-bis(bromomethyl)-2-fluorobenzene, 1,4-bis(bromomethyl)-2-chlorobenzene, 2-bromo-1,4-bis(bromomethyl)benzene, 1,4-bis(chloromethyl)-2-nitrobenzene, 1,4-bis(bromomethyl)-2,3,5,6-tetrafluorobenzene, α,α′,2,3,5,6-hexachloro-p-xylene, 1,2,4,5-tetrabromo-3,6-bis(bromomethyl)benzene, 1,2-dibromo-3,6-bis(chloromethyl)-4,5-dimethylbenzene, 1,4-bis(bromomethyl)-2,5-dimethylbenzene, 4,4′-bis(chloromethyl)biphenyl, 2,6-bis(bromomethyl)naphthalene, 1,5-bis(chloromethyl)naphthalene and the like.

In a case where the elements disposed at both ends of the skeleton of the first precursor compound have a structure derived from the second raw material, as the third raw material, similar to the first raw material, an aromatic compound having two phenolic hydroxyl groups can be used. In addition, as the third raw material, an aromatic compound having one phenolic hydroxyl group and an amino group or a carboxyalkyl group may also be used. Specific examples thereof include methylhydroquinone, hydroquinone, tetramethylhydroquinone, trimethylhydroquinone, 2-(trifluoromethyl)-1,4-benzenediol, fluorohydroquinone, chlorohydroquinone, bromohydroquinone, 2,5-dihydroxynitrobenzene, tetrafluorohydroquinone, tetrachlorohydroquinone, tetrabromohydroquinone, 2,6-dihydroxynaphthalene, 1,5-dihydroxynaphthalene, 4,4′-dihydroxybiphenyl, 3,3′,5,5′-tetramethylbiphenyl-4,4′-diol, 4-aminophenol, 4-amino-m-cresol, methyl 4-hydroxybenzoate and the like.

Next, the second precursor compound obtained by the reaction between the first precursor compound and the third raw material and a compound having a structure from which the end group having an epoxy group is to be derived are reacted with each other to obtain the epoxy resin of the present embodiment.

In addition, the epoxy resin of the present embodiment may also be produced by, for example, a method in which the second precursor compound and an olefin compound are reacted with each other to bond a group that is derived from the olefin compound to an end of the second precursor compound and then an end of the group that is derived from the olefin compound is converted into an epoxy group using an oxidant such as meta-chloroperoxybenzoic acid (mCPBA) or hydrogen peroxide.

In the case of producing an epoxy resin having a structure in which the first aromatic cyclic group and the third aromatic cyclic group are identical to each other or a structure in which the second aromatic cyclic group and the third aromatic cyclic group are identical to each other as the epoxy resin, there are cases where the step of reacting the first precursor compound and the third raw material is skipped.

Specifically, there are cases where an epoxy resin is obtained by reacting the first precursor compound and a compound having a structure from which the end group having an epoxy group is to be derived. In addition, there are cases where an epoxy resin can be produced by a method in which the first precursor compound and an olefin compound are reacted with each other to bond a group that is derived from the olefin compound to an end of the first precursor compound and then an end of the group that is derived from the olefin compound is converted into an epoxy group using an oxidant such as meta-chloroperoxybenzoic acid (mCPBA) or hydrogen peroxide.

The epoxy resin that is obtained by the production method of the present embodiment has, between the end groups each having an epoxy group that are disposed at both ends respectively, the first structure in which an aromatic cyclic group, an ether oxygen, a methylene group, an aromatic cyclic group, a methylene group, an ether oxygen and an aromatic cyclic group are bonded together in this order and/or the second structure in which an aromatic cyclic group, a methylene group, an ether oxygen, an aromatic cyclic group, an ether oxygen, a methylene group and an aromatic cyclic group are bonded together in this order.

In the method for producing the epoxy resin of the present embodiment, it is preferable to generate a mixture including a plurality of kinds of epoxy resins having different numbers of repeating units at the same time. In the case of producing a cured product using the epoxy resin of the present embodiment, there are cases where a plurality of kinds of the epoxy resin of the present embodiment is preferably mixed together and used depending on applications or the like. In the case of generating the mixture including a plurality of kinds of epoxy resins having different numbers of repeating units at the same time, there are cases where a cured product can be efficiently produced without performing a step of mixing the plurality of kinds of epoxy resins of the present embodiment at the time of producing the cured product using the epoxy resin of the present embodiment.

In the method for producing the epoxy resin of the present embodiment, after the mixture including the plurality of kinds of epoxy resins having different numbers of repeating units is generated at the same time, a single epoxy resin having a specific molecular weight may be separated from the mixture of the plurality of kinds of epoxy resins using a well-known method as necessary.

The epoxy resin of the present embodiment preferably includes a skeleton having a symmetric structure in which the first aromatic cyclic units and the second aromatic cyclic units are alternately disposed. This skeleton has a structure in which aromatic cyclic groups that are each a mesogenic group developing liquid crystallinity and impart rigidity (the first aromatic cyclic group and the second aromatic cyclic group), methylene groups and ether oxygens that impart mobility are disposed in a specific order. Due to this fact, the epoxy resin of the present embodiment is capable of stabilizing a smectic liquid crystal phase with appropriate mobility intrinsic to the mesogenic groups in spite of having no long side chains which are typically observable in liquid crystal molecules. Therefore, the epoxy resin of the present embodiment has high orientation, and a cured product which has a smectic liquid crystal structure and is highly thermally conductive due to suppression of the scattering of phonons can be obtained by curing the epoxy resin of the present embodiment.

### “Resin Composition”

A resin composition of the present embodiment contains the above-described epoxy resin of the present embodiment as a resin component, and the number of the kinds of epoxy resins of the present embodiment that the resin composition contains may be only one or two or more.

It is preferable that the resin composition of the present embodiment contains the above-described epoxy resin of the present embodiment as a resin component and further contains a curing agent and a curing accelerator (catalyst).

Examples of the curing agent include p-phenylenediamine, 1,5-diaminonaphthalene, hydroquinone, 2,6-dihydroxynaphthalene, phloroglucinol, 4-hydroxybenzoic acid, 6-hydroxy-2-naphthoic acid, 4-aminobenzoic acid, a phenolic resin, polyamideamine, and the like. As the curing agent, among the above-described curing agents, particularly, 4-aminobenzoic acid is preferably used since a cured product having higher thermally conductive properties can be obtained.

The amount of the curing agent can be optionally selected, and, for example, the curing agent is used in an amount in which the total amount of functional groups capable of causing a curing reaction with the epoxy groups ordinarily reaches 0.5 to 1.5 parts by equivalent and preferably reaches 0.9 to 1.1 parts by equivalent with respect to the total amount of the epoxy groups in the resin component.

As the curing accelerator, it is possible to use, for example, a basic organic compound having a high boiling point or the like. Specific examples thereof include polymerization accelerators having a boiling point of 200° C. or higher selected from tertiary amines, tertiary phosphines, 4-dimethylaminopyridine (DMAP) or imidazoles and the like. Among these, particularly, 2-ethyl-4-methylimidazole (2E4MZ) and 1-(2-cyanoethyl)-2-phenylimidazole, which are imidazole-based epoxy resin curing agents, are preferably used as the curing accelerator due to easiness in handling.

The amount of the content of the curing accelerator in the resin composition can be optionally selected and is, for example, 0 to 5 parts by mass with respect to a total of 100 parts by mass of the resin component and the curing agent. The amount of the curing accelerator may be 0.5 to 5 parts by mass, 1 to 3 parts by mass, 2 to 4 parts by mass or the like.

The resin composition of the present embodiment may contain a resin component other than the epoxy resin of the present embodiment as necessary as long as the effect of containing the epoxy resin of the present embodiment can be obtained. As the resin component other than the epoxy resin of the present embodiment, for example, one or more of compounds such as an epoxy compound such as 4,4-biphenyl glycidyl ether, a compound having an amino group such as p-phenylenediamine and a compound having an amide group such as sulfanilamide may be contained.

The resin composition of the present embodiment may contain inorganic particles as necessary. Examples of the inorganic particles include boron nitride particles, magnesium oxide particles, alumina particles, aluminum hydroxide particles, aluminum nitride particles, silica particles and the like. As the inorganic particles, among these, one kind of inorganic particles may be used singly or a combination of two or more kinds of inorganic particles may be used.

The amount of the inorganic particles can be optionally selected, but is preferably 200 to 700 parts by mass and more preferably 300 to 600 parts by mass with respect to a total of 100 parts by mass of the resin composition components other than the inorganic particles. The amount of the inorganic particles may be 200 to 500 parts by mass, 200 to 400 parts by mass, 200 to 300 parts by mass, 400 to 500 parts by mass or the like. When the amount of the inorganic particles is 200 parts by mass or more, an effect of improving the thermally conductive properties of the resin composition in cured products becomes significant. In addition, when the amount of the inorganic particles is 700 parts by mass or less, sufficient formability can be obtained at the time of forming a resin substrate using the cured product of the resin composition.

The resin composition of the present embodiment may contain a solvent as necessary. Examples of the solvent include ketones such as acetone and methyl ethyl ketone (MEK), alcohols such as methanol, ethanol and isopropanol, aromatic compounds such as toluene and xylene, ethers such as tetrahydrofuran (THF) and 1,3-dioxolane, esters such as ethyl acetate and y-butyrolactone, amides such as N,N-dimethylformamide (DMF) and N-methylpyrrolidone, and the like. As the solvent, among these, one solvent may be used singly or a combination of two or more solvents may be used.

The amount of the solvent in the resin composition can be optionally selected as necessary and is, for example, 0 to 500 parts by mass with respect to a total of 100 parts by mass of the resin component and the curing agent. The amount of the solvent may be 0 to 400 parts by mass, 5 to 300 parts by mass, 10 to 200 parts by mass, 100 to 200 parts by mass or the like.

The resin composition may contain a random component other than the above-described components as necessary. Examples of the random component include a coupling agent such as a silane coupling agent or a titanate coupling agent, a flame retardant such as halogen, a plasticizer, a lubricant and the like.

The resin composition of the present embodiment can be produced by, for example, a method in which a resin component containing the above-described epoxy resin of the present embodiment, a curing agent, a curing accelerator and a different component that is contained as necessary are mixed together.

Since the resin composition of the present embodiment contains the above-described epoxy resin of the present embodiment, a cured product having a high thermal conductivity can be obtained by curing the resin composition.

### “Resin Sheet”

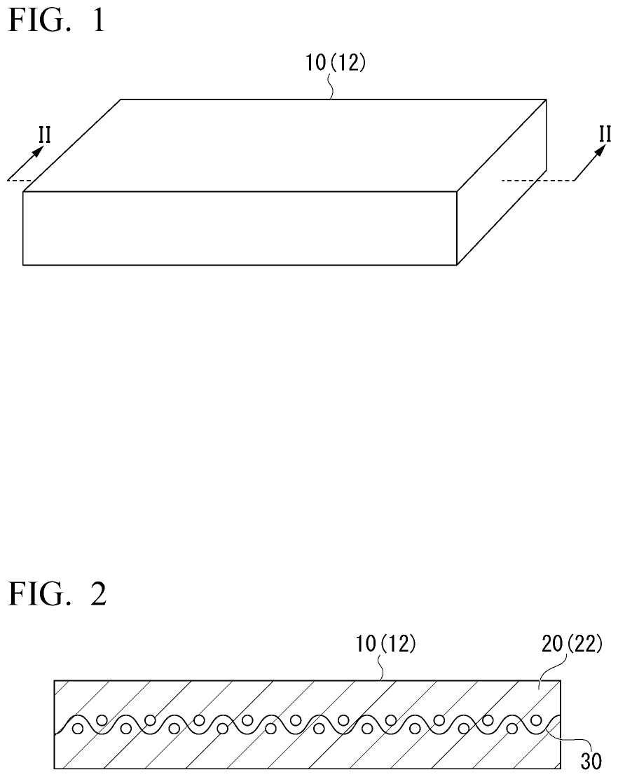

FIG. 1 is a schematic perspective view showing an example of a resin sheet and a resin substrate according to an embodiment. A resin sheet 12 shown in FIG. 1 is a sheet obtained by forming a resin composition. The resin sheet 12 may contain the resin composition as it is or may contain the resin composition that is partially or entirely put into a B stage (semi-cured) state.

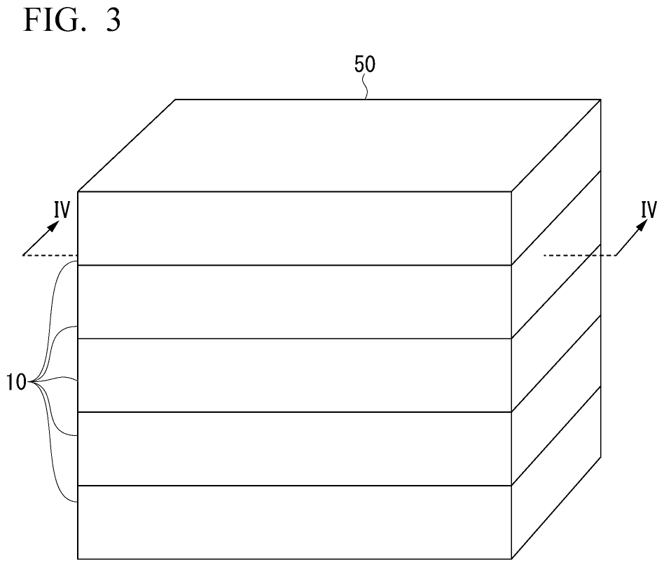

FIG. 2 is a cross-sectional view taken along a line II-II in FIG. 1. FIG. 2 shows a cross section of the resin sheet 12 at the time of being cut along the thickness direction. The resin sheet 12 contains a core 30 and a resin component 22 with which the core 30 is impregnated and which covers both surfaces of the core 30. o in FIG. 2 indicates a glass fiber that is contained in the core 30. The resin component 22 may be an uncured resin composition or a resin composition that is partially or entirely in a semi-cured state.

Examples of the core 30 include a woven fabric, a non-woven fabric and the like. Examples of the material of the woven fabric and the non-woven fabric include at least one kind of fiber selected from a glass fiber, a carbon fiber, a metal fiber, a natural fiber, a synthetic fiber such as a polyester fiber or a polyamide fiber and the like.

The resin sheet 12 can be produced as described below.

The core 30 is impregnated with the resin composition by a method such as application or immersion. In a case where the resin composition contains a solvent, the core 30 is heated and dried after being impregnated with the resin composition, thereby removing the solvent. The heating conditions for removing the solvent in the resin composition can be optionally selected, for example, the core can be heated at 60° C. to 150° C. for approximately 1 to 120 minutes and is preferably heated at 70° C. to 120° C. for approximately 3 to 90 minutes.

In the resin sheet 12, in a case where a part or all of the resin component 22 is a semi-cured product of the resin composition, at the same time as the heating for removing the solvent in the resin composition, a part or all of the resin composition with which the core 30 has been impregnated is cured and put into a semi-cured state. In addition, after the heating for removing the solvent in the resin composition, a part or all of the resin composition with which the core 30 has been impregnated may be cured and put into a semi-cured state under the same conditions as those for the heating for removing the solvent in the resin composition.

The resin sheet 12 having the resin component 22 composed of the resin composition that is not cured or has been at least partially semi-cured is obtained by the above-described steps.

Since the resin sheet 12 shown in FIG. 1 is obtained by forming the resin composition of the present embodiment, a resin cured product having a high thermal conductivity can be obtained by thermally treating the resin sheet 12 to cure the resin composition. Therefore, the resin sheet 12 shown in FIG. 1 is preferable as a material for resin substrates.

The resin sheet 12 of the present embodiment can be used as a precursor of resin substrates (resin cured products) containing a cured product of the resin composition.

In the present embodiment, the resin sheet 12 has been described using a resin sheet having the core 30 as shown in FIG. 2 as an example, but the resin sheet of the present disclosure may be a resin sheet that has no core and is formed of a resin component alone.

In addition, a metal foil such as a copper foil may be laminated on the surface of the resin sheet.

### “Resin Cured Product and Resin Substrate”

A resin substrate 10 (resin cured product) of the present embodiment shown in FIG. 1 and FIG. 2 is obtained by thermally curing the resin component 22 that is contained in the resin sheet 12 and contains a cured product 20 of the resin composition of the present embodiment.

The resin substrate 10 of the present embodiment can be produced by a method in which the above-described resin sheet 12 of the present embodiment is used as a precursor and the resin sheet 12 is heated.

Specifically, the resin sheet 12 of the present embodiment is heated to thermally cure the resin component 22 in an uncured state or a semi-cured state, thereby producing the cured product 20. The heating conditions for curing the resin component 22 can be selected as necessary and are preferably set to, for example, 100° C. to 250° C. for approximately 1 to 300 minutes. The heating for curing the resin component 22 may be performed under increased pressure or reduced pressure as necessary.

The resin substrate 10 of the present embodiment is a resin cured product containing a cured product of the resin composition of the present embodiment and thus has a high thermal conductivity.

In the present embodiment, the resin substrate 10 (resin cured product) has been described using a resin substrate containing the core 30 and the cured product 20 that covers the core 30 as shown in FIG. 2 as an example, but the resin cured product and the resin substrate of the present disclosure may be composed of a cured product of the resin composition alone.

In addition, the resin cured product and the resin substrate of the present disclosure may be produced by, for example, heating an irregular resin composition as in a case where the resin composition is used as an adhesive.

### “Multilayer Substrate”

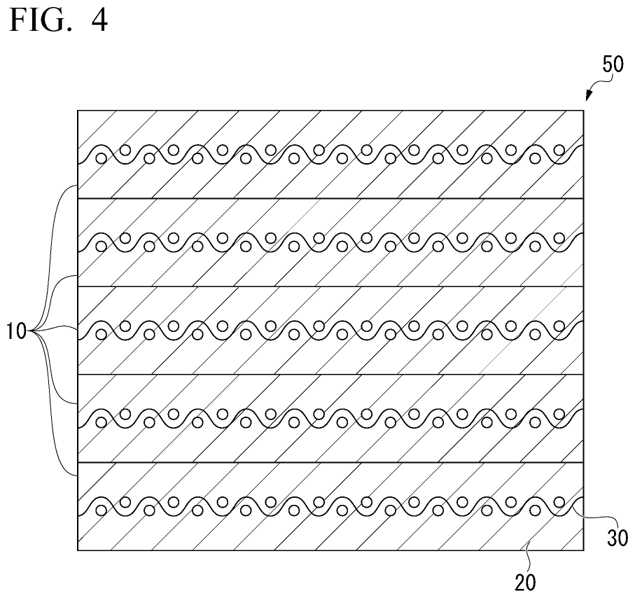

FIG. 3 is a schematic perspective view of a multilayer substrate according to an embodiment. FIG. 4 is a cross-sectional view taken along a line IV-IV in FIG. 3. FIG. 4 shows a cross section of the multilayer substrate at the time of being cut along the lamination direction. As shown in FIG. 3 and FIG. 4, in a multilayer substrate 50, a plurality of the resin substrates 10 shown in FIG. 2 is laminated and integrated together.

The multilayer substrate 50 can be produced by, for example, a method in which a plurality of the resin substrates 10 is heated in an overlapped state. The multilayer substrate 50 may also be produced by a method in which a plurality of the resin sheets 12 is heated in an overlapped state to thermally cure the resin component in a non-cured state or a semi-cured state, thereby producing the cured product 20. The heating conditions of the plurality of resin substrates 10 and the heating conditions for the plurality of resin sheets 12 can be set to, for example, 100° C. to 250° C. for approximately 1 to 300 minutes.

At the time of being heated, the plurality of resin substrates 10 or the plurality of resin sheets 12 may be pressurized as necessary. The pressurization condition can be set to, for example, approximately 0.1 to 10 MPa. At the time of heating the plurality of resin substrates 10 or the plurality of resin sheets 12, the pressurization is not essential, and the plurality of resin substrates 10 or the plurality of resin sheets 12 may be heated under reduced pressure or in a vacuum.

The multilayer substrate 50 of the present embodiment includes the resin substrates 10 in a laminated state and thus has a high thermal conductivity.

In the present embodiment, the multilayer substrate 50 has been described using a multilayer substrate in which a plurality of the resin substrates 10, which is shown in FIG. 2, containing the cured product 20 of the resin composition is laminated as an example, but the multilayer substrate of the present disclosure may be a resin substrate in which, among a plurality of resin substrates, at least one resin substrate contains a cured product of the resin composition of the present disclosure.

In addition, the multilayer substrate of the present disclosure may be produced as a metal-clad multilayer sheet having metal layers on the upper surface and/or the lower surface. In this case, as the metal layer, a variety of well-known metal layers can be appropriately selected and used. Specifically, as the metal layer, for example, a metal sheet, metal foil or the like made of a metal such as copper, nickel or aluminum can be used. The thickness of the metal layer is not particularly limited and can be set to, for example, approximately 3 to 150 μm. As the metal layer, a metal sheet or metal foil that has been etched and/or punched may be used.

Hitherto, the embodiment of the present disclosure has been described in detail with reference to the drawings, but each constitution in each embodiment, a combination thereof, and the like are examples, and the addition, omission, substitution, and other modification of the constitution are possible within the scope of the gist of the present disclosure.

### EXAMPLES

### <Synthesis of Epoxy Resins>

### Synthesis Example 1 to Synthesis Example 52

Epoxy resins of Synthesis Example 1 to Synthesis Example 52 which were the epoxy resin represented by General Formula (1) and in which the first aromatic cyclic group that is indicated by Ar₁ and the third aromatic cyclic group that is indicated by Ar₃ in Formula (1) were identical to each other and Z in Formula (1) was the end group indicated by Formula (3) were synthesized by a method described below.

A first raw material shown in Table 1 and Table 2 and a second raw material shown in Table 1 and Table 2 were weighed, respectively, to fractions shown in Table 1 and Table 2 in a three-neck flask and dissolved in 1 L of tetrahydrofuran (THL), thereby obtaining a first mixed solution. After that, the first mixed solution was refluxed in a nitrogen stream to remove dissolved oxygen in the first mixed solution. Next, twice as many substance amount (number of moles) of potassium carbonate as that of the second raw material were added to the first mixed solution, the refluxed state was held for 12 hours, and a reaction was caused.

After the end of the reaction, the obtained suspension was poured into water and stirred for 30 minutes, and the generated precipitate was filtered and recovered. The recovered precipitate was dried in a vacuum for 12 hours or longer and dissolved in THF (1 L), and epichlorohydrin (300 g) was added thereto, thereby producing a second mixed solution. After that, the second mixed solution was refluxed in a nitrogen stream to remove dissolved oxygen in the second mixed solution. Next, a 50% aqueous solution of sodium hydroxide (25 g) was added to the second mixed solution, the refluxed state was held for 12 hours, and a reaction was caused.

After the end of the reaction, the obtained suspension was poured into water and stirred for 30 minutes, and the generated precipitate was filtered and recovered. The recovered precipitate was dried in a vacuum for 12 hours or longer, thereby obtaining an epoxy resin of each of Synthesis Example 1 to Synthesis Example 52.

### Synthesis Example 53

An epoxy resin of Synthesis Example 53 which was the epoxy resin represented by General Formula (1) and in which, in Formula (1), the first aromatic cyclic group that is indicated by Ar₁ and the third aromatic cyclic group that is indicated by Ar₃ were a para-phenylene group having one methyl group, the second aromatic cyclic group that is indicated by Ar₂ was a para-phenylene group having no substituent and Z in Formula (1) was the end group indicated by Formula (4) was synthesized by a method described below.

A first raw material shown in Table 2 and a second raw material shown in Table 2 were weighed, respectively, to fractions shown in Table 2 in a three-neck flask and dissolved in 1 L of tetrahydrofuran (THL), thereby obtaining a first mixed solution. After that, the first mixed solution was refluxed in a nitrogen stream to remove dissolved oxygen in the first mixed solution. Next, twice as many substance amount (number of moles) of potassium carbonate as that of the second raw material were added to the first mixed solution, the refluxed state was held for 12 hours, and a reaction was caused.

After the end of the reaction, the obtained suspension was poured into water and stirred for 30 minutes, and the generated precipitate was filtered and recovered. The recovered precipitate was dried in a vacuum for 12 hours or longer and dissolved in THF (1 L), and 1-bromo-4-butene (40.5 g, 0.30 mol) was added thereto, thereby producing a second mixed solution. After that, the second mixed solution was refluxed in a nitrogen stream to remove dissolved oxygen in the second mixed solution. Next, a 50% aqueous solution of sodium hydroxide (25 g) was added to the second mixed solution, the refluxed state was held for 12 hours, and a reaction was caused.

After the end of the reaction, the obtained suspension was poured into water and stirred for 30 minutes, and the generated precipitate was filtered and recovered. The recovered precipitate was dried in a vacuum for 12 hours or longer and dissolved in chloroform, and meta-chloroperoxybenzoic acid (mCPBA) (50 g, 0.29 mol) was added thereto at intervals, thereby producing a third mixed solution. After that, the third mixed solution was reacted at room temperature for eight hours to be concentrated under reduced pressure until the liquid amount of the third mixed solution was reduced approximately by half. The obtained suspension was poured into methanol (MeOH) and stirred for 30 minutes, and the generated precipitate was filtered and recovered. The recovered precipitate was dried in a vacuum for 12 hours, thereby obtaining an epoxy resin of Synthesis Example 53.

### Synthesis Example 54

An epoxy resin of Synthesis Example 54 which was the epoxy resin represented by General Formula (1) and in which, in Formula (1), the first aromatic cyclic group that is indicated by Ar₁ was a para-phenylene group having one methyl group, the second aromatic cyclic group that is indicated by Ar₂ and the third aromatic cyclic group that is indicated by Ar₃ were a para-phenylene group having no substituent and Z in Formula (1) was the end group indicated by Formula (5) was synthesized by a method described below.

A first raw material shown in Table 2 and a second raw material shown in Table 2 were weighed, respectively, to fractions shown in Table 2 in a three-neck flask and dissolved in 1 L of tetrahydrofuran (THL), thereby obtaining a first mixed solution. After that, the first mixed solution was refluxed in a nitrogen stream to remove dissolved oxygen in the first mixed solution. Next, twice as many substance amount (number of moles) of potassium carbonate as that of the first raw material were added to the first mixed solution, the refluxed state was held for 12 hours, and a reaction was caused.

Next, methyl 4-hydroxybenzoate, which was a third raw material, (22.8 g, 0.15 mol) and potassium carbonate (41.4 g, 0.30 mol) were added to the first mixed solution, thereby producing a second mixed solution. This second mixed solution was held in the refluxed state for 12 hours and reacted. After that, water was added to the second mixed solution, and the second mixed solution was further refluxed for six hours.

After the end of the reaction, the obtained suspension was poured into water, neutralized with hydrochloric acid such that the pH reached six or lower and stirred for 30 minutes, and the generated precipitate was filtered and recovered. The recovered precipitate was dried in a vacuum for 12 hours or longer and dissolved in THF (1 L), and epichlorohydrin (300 g) was added thereto, thereby producing a third mixed solution. After that, the third mixed solution was refluxed in a nitrogen stream to remove dissolved oxygen in the third mixed solution. Next, potassium carbonate (41.5 g, 0.3 mol) was added to the third mixed solution, the refluxed state was held for 12 hours, and a reaction was caused.

After the end of the reaction, the obtained suspension was poured into water and stirred for 30 minutes, and the generated precipitate was filtered and recovered. The recovered precipitate was dried in a vacuum for 12 hours or longer, thereby obtaining an epoxy resin of Synthesis Example 54.

### Synthesis Example 55

An epoxy resin of Synthesis Example 55 which was the epoxy resin represented by General Formula (1) and in which, in Formula (1), the first aromatic cyclic group that is indicated by Art was a para-phenylene group having one methyl group, the second aromatic cyclic group that is indicated by Ar₂ was a para-phenylene group having no substituent, the third aromatic cyclic group that is indicated by Ar₃ was a para-phenylene group having no substituent and Z in Formula (1) was the end group indicated by Formula (6) was synthesized by a method described below.

The precipitate that was used in the third mixed solution in Synthesis Example 54 was dissolved in N,N-dimethylformamide (DMF) (1 L), thionyl chloride (35.7 g, 0.3 mol) was added thereto dropwise, and the precipitate and thionyl chloride were held at 90° C. and reacted with each other.

After the end of the reaction, thionyl chloride and a solvent were distilled away under reduced pressure, DMF and triethylamine (30 g) were added to the inside of a reaction container, 1-amino-3-propene (8.6 g, 0.15 mol) was added thereto dropwise, and the components were stirred for eight hours and reacted with each other. After that, the obtained reaction mixture was poured into water and stirred for 30 minutes, and the generated precipitate was filtered and recovered.

The recovered precipitate was dissolved in chloroform, meta-chloroperoxybenzoic acid (mCPBA) (50 g, 0.29 mol) was added thereto at intervals, and the recovered precipitate and meta-chloroperoxybenzoic acid were reacted with each other at room temperature for eight hours. The obtained suspension was concentrated under reduced pressure until the liquid amount was reduced approximately by half, poured into methanol (MeOH) and stirred for 30 minutes, and the generated precipitate was filtered and recovered. The recovered precipitate was dried in a vacuum for 12 hours, thereby obtaining an epoxy resin of Synthesis Example 55.

### Synthesis Example 56

An epoxy resin of Synthesis Example 56 which was the epoxy resin represented by General Formula (1) and in which, in Formula (1), the first aromatic cyclic group that is indicated by Ar₁ and the third aromatic cyclic group that is indicated by Ar₃ were a para-phenylene group having one methyl group, the second aromatic cyclic group that is indicated by Ar₂ was a para-phenylene group having no substituent and Z in Formula (1) was the end group indicated by Formula (7) was synthesized by a method described below.

A first raw material shown in Table 2 and a second raw material shown in Table 2 were weighed, respectively, to fractions shown in Table 2 in a three-neck flask and dissolved in 1 L of tetrahydrofuran (THL), thereby obtaining a first mixed solution. After that, the first mixed solution was refluxed in a nitrogen stream to remove dissolved oxygen in the first mixed solution. Twice as many substance amount (number of moles) of potassium carbonate as that of the first raw material were added thereto, the refluxed state was held for 12 hours, and a reaction was caused.

After the end of the reaction, 4-amino-m-cresol, which was a third raw material, (36.9 g, 0.3 mol) and potassium carbonate (41.4 g, 0.3 mol) were added to the first mixed solution, thereby producing a second mixed solution. After that, the second mixed solution was refluxed for 12 hours. The obtained suspension was poured into water and stirred for 30 minutes, and the generated precipitate was filtered and recovered. The recovered precipitate was dried in a vacuum for 12 hours or longer and dissolved in THF (1 L), and epichlorohydrin (400 g) was added thereto, thereby producing a third mixed solution. After that, the third mixed solution was refluxed in a nitrogen stream to remove dissolved oxygen in the third mixed solution. Next, a 50% aqueous solution of sodium hydroxide (60 g) was added to the third mixed solution, the refluxed state was held for 12 hours, and a reaction was caused.

After the end of the reaction, the obtained suspension was poured into water and stirred for 30 minutes, and the generated precipitate was filtered and recovered. The recovered precipitate was dried in a vacuum for 12 hours or longer, thereby obtaining an epoxy resin of Synthesis Example 56.

### Synthesis Example 57

An epoxy resin of Synthesis Example 57 which was the epoxy resin represented by General Formula (1) and in which, in Formula (1), the first aromatic cyclic group that is indicated by Ar₁ was a para-phenylene group having one methyl group, the second aromatic cyclic group that is indicated by Ar₂ and the third aromatic cyclic group that is indicated by Ar₃ were a para-phenylene group having no substituent and Z in Formula (1) was the end group indicated by Formula (7) was synthesized by a method described below.

A first raw material shown in Table 2 and a second raw material shown in Table 2 were weighed, respectively, to fractions shown in Table 2 in a three-neck flask and dissolved in 1 L of tetrahydrofuran (THL), thereby obtaining a first mixed solution. After that, the first mixed solution was refluxed in a nitrogen stream to remove dissolved oxygen in the first mixed solution. Twice as many substance amount (number of moles) of potassium carbonate as that of the first raw material were added thereto, the refluxed state was held for 12 hours, and a reaction was caused.

After the end of the reaction, 4-aminophenol, which was a third raw material, (32.7 g, 0.3 mol) and potassium carbonate (41.4 g, 0.3 mol) were added to the first mixed solution, thereby producing a second mixed solution. After that, the second mixed solution was refluxed for 12 hours. The obtained suspension was poured into water and stirred for 30 minutes, and the generated precipitate was filtered and recovered. The recovered precipitate was dried in a vacuum for 12 hours or longer and dissolved in THF (1 L), and epichlorohydrin (400 g) was added thereto, thereby producing a third mixed solution. After that, the third mixed solution was refluxed in a nitrogen stream to remove dissolved oxygen in the third mixed solution. Next, a 50% aqueous solution of sodium hydroxide (60 g) was added to the third mixed solution, the refluxed state was held for 12 hours, and a reaction was caused.

After the end of the reaction, the obtained suspension was poured into water and stirred for 30 minutes, and the generated precipitate was filtered and recovered. The recovered precipitate was dried in a vacuum for 12 hours or longer, thereby obtaining an epoxy resin of Synthesis Example 57.

### Synthesis Example 58

An epoxy resin of Synthesis Example 58 which was the epoxy resin represented by General Formula (1) and in which, in Formula (1), the first aromatic cyclic group that is indicated by Ar₁ was a para-phenylene group having one methyl group, the second aromatic cyclic group that is indicated by Ar₂ and the third aromatic cyclic group that is indicated by Ar₃ were a para-phenylene group having no substituent and Z in Formula (1) was the end group indicated by Formula (8) was synthesized by a method described below.

A first raw material shown in Table 2 and a second raw material shown in Table 2 were weighed, respectively, to fractions shown in Table 2 in a three-neck flask and dissolved in 1 L of tetrahydrofuran (THL), thereby obtaining a first mixed solution. After that, the first mixed solution was refluxed in a nitrogen stream to remove dissolved oxygen in the first mixed solution. Next, a 50% aqueous solution of sodium hydroxide (80 g) was added to the first mixed solution, the refluxed state was held for 12 hours, and a reaction was caused.

After the end of the reaction, the obtained reaction solution was left to stand in the air such that the temperature reached room temperature, adjusted with hydrochloric acid such that the pH reached four to six and stirred for 30 minutes, and the generated precipitate was filtered and recovered. The recovered precipitate was dried in a vacuum for 12 hours or longer and dissolved in THF (1 L), and epichlorohydrin (300 g) was added thereto, thereby producing a second mixed solution. After that, the second mixed solution was refluxed in a nitrogen stream to remove dissolved oxygen in the second mixed solution. Next, potassium tert-butoxide (t-BuOK) (33.7 g, 0.3 mol) was added to the second mixed solution, the refluxed state was held for 12 hours, and a reaction was caused.

After the end of the reaction, the obtained suspension was poured into water and stirred for 30 minutes, and the generated precipitate was filtered and recovered. The recovered precipitate was dried in a vacuum for 12 hours or longer, thereby obtaining an epoxy resin of Synthesis Example 58.

TABLE 1

| | | | First | Second | | | | | | | | | | | | Average | |
|---|---|---|---|---|---|---|---|---|---|---|---|---|---|---|---|---|---|
| | First | Second | raw | raw | | | | | | | | | | | | poly- | |
| | raw | raw | material | material | Number of repeating units n (mol %) | | | | | | | | | | | merization | |
| Epoxy resin | material | material | (mol) | (mol) | | 1 | 2 | 3 | 4 | 5 | 6 | 7 | 8 | 9 | 10 | degree | End group |
| Synthesis Example 1 | 1-1 | 2-1 | 0.477 | 0.273 | 27 | 30 | 28 | 10 | 5 | | | | | | | 2.4 | Formula (3) |
| Synthesis Example 2 | 1-1 | 2-1 | 0.450 | 0.300 | 5 | 18 | 33 | 23 | 14 | 5 | 2 | | | | | 3.5 | Formula (3) |
| Synthesis Example 3 | 1-1 | 2-1 | 0.438 | 0.313 | | 5 | 8 | 17 | 25 | 21 | 16 | 8 | | | | 5.3 | Formula (3) |
| Synthesis Example 4 | 1-1 | 2-1 | 0.424 | 0.326 | | | 2 | 7 | 11 | 15 | 16 | 17 | 14 | 10 | 8 | 7.4 | Formula (3) |
| Synthesis Example 5 | 1-1 | 2-1 | 0.409 | 0.341 | | | | | | | 11 | 26 | 29 | 21 | 13 | 9.0 | Formula (3) |
| Synthesis Example 6 | 1-1 | 2-1 | 0.643 | 0.107 | 85 | 15 | | | | | | | | | | 1.2 | Formula (3) |
| Synthesis Example 7 | 1-2 | 2-1 | 0.450 | 0.300 | 11 | 19 | 27 | 22 | 14 | 7 | | | | | | 3.3 | Formula (3) |
| Synthesis Example 8 | 1-2 | 2-2 | 0.450 | 0.300 | 14 | 20 | 21 | 18 | 11 | 9 | 5 | 2 | | | | 3.5 | Formula (3) |
| Synthesis Example 9 | 1-1 | 2-2 | 0.450 | 0.300 | 19 | 24 | 21 | 16 | 10 | 6 | 3 | 1 | | | | 3.1 | Formula (3) |
| Synthesis Example 10 | 1-3 | 2-1 | 0.450 | 0.300 | 3 | 13 | 20 | 24 | 18 | 11 | 7 | 3 | 1 | | | 4.2 | Formula (3) |
| Synthesis Example 11 | 1-2 | 2-3 | 0.450 | 0.300 | 2 | 11 | 22 | 26 | 21 | 12 | 6 | | | | | 4.1 | Formula (3) |
| Synthesis Example 12 | 1-3 | 2-3 | 0.450 | 0.300 | 1 | 8 | 20 | 24 | 22 | 17 | 8 | | | | | 4.4 | Formula (3) |
| Synthesis Example 13 | 1-4 | 2-1 | 0.450 | 0.300 | 12 | 19 | 23 | 21 | 16 | 8 | 1 | | | | | 3.4 | Formula (3) |
| Synthesis Example 14 | 1-5 | 2-1 | 0.450 | 0.300 | 4 | 18 | 26 | 23 | 16 | 11 | 2 | | | | | 3.7 | Formula (3) |
| Synthesis Example 15 | 1-6 | 2-1 | 0.450 | 0.300 | 20 | 25 | 21 | 16 | 11 | 5 | 2 | | | | | 3.0 | Formula (3) |
| Synthesis Example 16 | 1-7 | 2-1 | 0.450 | 0.300 | 20 | 22 | 19 | 15 | 11 | 8 | 3 | 2 | | | | 3.2 | Formula (3) |
| Synthesis Example 17 | 1-8 | 2-1 | 0.450 | 0.300 | 14 | 26 | 24 | 18 | 10 | 6 | 2 | | | | | 3.1 | Formula (3) |
| Synthesis Example 18 | 1-9 | 2-1 | 0.450 | 0.300 | 1 | 6 | 18 | 24 | 21 | 16 | 9 | 5 | | | | 4.7 | Formula (3) |
| Synthesis Example 19 | 1-5 | 2-2 | 0.450 | 0.300 | 19 | 25 | 23 | 16 | 9 | 6 | 2 | | | | | 3.0 | Formula (3) |
| Synthesis Example 20 | 1-6 | 2-2 | 0.450 | 0.300 | 10 | 19 | 25 | 23 | 15 | 8 | | | | | | 3.4 | Formula (3) |
| Synthesis Example 21 | 1-7 | 2-2 | 0.450 | 0.300 | 14 | 20 | 23 | 18 | 12 | 7 | 4 | 2 | | | | 3.4 | Formula (3) |
| Synthesis Example 22 | 1-8 | 2-2 | 0.450 | 0.300 | 3 | 9 | 17 | 24 | 19 | 15 | 8 | 4 | 1 | | | 4.5 | Formula (3) |
| Synthesis Example 23 | 1-9 | 2-2 | 0.450 | 0.300 | 19 | 24 | 22 | 16 | 11 | 5 | 3 | | | | | 3.0 | Formula (3) |
| Synthesis Example 24 | 1-1 | 2-4 | 0.450 | 0.300 | 7 | 13 | 24 | 19 | 14 | 11 | 8 | 4 | | | | 4.1 | Formula (3) |
| Synthesis Example 25 | 1-1 | 2-5 | 0.450 | 0.300 | 18 | 23 | 26 | 19 | 10 | 4 | | | | | | 2.9 | Formula (3) |
| Synthesis Example 26 | 1-1 | 2-6 | 0.450 | 0.300 | 14 | 22 | 23 | 19 | 13 | 7 | | | | | | 3.1 | Formula (3) |
| Synthesis Example 27 | 1-1 | 2-7 | 0.450 | 0.300 | 4 | 10 | 19 | 21 | 17 | 12 | 9 | 5 | 3 | | | 4.5 | Formula (3) |
| Synthesis Example 28 | 1-6 | 2-4 | 0.450 | 0.300 | 6 | 10 | 19 | 22 | 17 | 12 | 8 | 4 | 2 | | | 4.3 | Formula (3) |
| Synthesis Example 29 | 1-6 | 2-5 | 0.450 | 0.300 | 17 | 25 | 22 | 17 | 12 | 7 | | | | | | 3.0 | Formula (3) |
| Synthesis Example 30 | 1-10 | 2-1 | 0.450 | 0.300 | 16 | 24 | 30 | 17 | 9 | 4 | | | | | | 2.9 | Formula (3) |

TABLE 2

| | | | First | Second | | | | | | | | | | | | Average | |
|---|---|---|---|---|---|---|---|---|---|---|---|---|---|---|---|---|---|
| | First | Second | raw | raw | | | | | | | | | | | | poly- | |
| | raw | raw | material | material | Number of repeating units n (mol %) | | | | | | | | | | | merization | |
| Epoxy resin | material | material | (mol) | (mol) | | 1 | 2 | 3 | 4 | 5 | 6 | 7 | 8 | 9 | 10 | degree | End group |
| Synthesis Example 31 | 1-11 | 2-1 | 0.450 | 0.300 | 15 | 20 | 27 | 18 | 13 | 7 | | | | | | 3.2 | Formula (3) |
| Synthesis Example 32 | 1-12 | 2-1 | 0.450 | 0.300 | 3 | 12 | 23 | 29 | 19 | 9 | 5 | | | | | 4.0 | Formula (3) |
| Synthesis Example 33 | 1-2 | 2-8 | 0.450 | 0.300 | 9 | 17 | 25 | 22 | 14 | 9 | 4 | | | | | 3.6 | Formula (3) |
| Synthesis Example 34 | 1-2 | 2-9 | 0.450 | 0.300 | 17 | 21 | 25 | 20 | 12 | 5 | | | | | | 3.0 | Formula (3) |
| Synthesis Example 35 | 1-2 | 2-10 | 0.450 | 0.300 | | 6 | 11 | 23 | 26 | 19 | 11 | 3 | 1 | | | 4.9 | Formula (3) |
| Synthesis Example 36 | 1-10 | 2-8 | 0.450 | 0.300 | 13 | 19 | 24 | 17 | 14 | 9 | 4 | | | | | 3.4 | Formula (3) |
| Synthesis Example 37 | 1-11 | 2-9 | 0.450 | 0.300 | 17 | 28 | 23 | 16 | 10 | 6 | | | | | | 2.9 | Formula (3) |
| Synthesis Example 38 | 1-12 | 2-10 | 0.450 | 0.300 | 12 | 17 | 22 | 18 | 13 | 10 | 6 | 2 | | | | 3.7 | Formula (3) |
| Synthesis Example 39 | 1-1 | 2-11 | 0.450 | 0.300 | 12 | 19 | 25 | 21 | 17 | 6 | | | | | | 3.3 | Formula (3) |
| Synthesis Example 40 | 1-1 | 2-12 | 0.450 | 0.300 | 16 | 18 | 22 | 17 | 12 | 8 | 4 | 2 | 1 | | | 3.5 | Formula (3) |
| Synthesis Example 41 | 1-1 | 2-13 | 0.450 | 0.300 | 15 | 21 | 24 | 19 | 13 | 8 | | | | | | 3.2 | Formula (3) |
| Synthesis Example 42 | 1-2 | 2-14 | 0.450 | 0.300 | 7 | 19 | 25 | 18 | 13 | 9 | 5 | 3 | 1 | | | 3.8 | Formula (3) |
| Synthesis Example 43 | 1-13 | 2-1 | 0.450 | 0.300 | 21 | 31 | 22 | 18 | 8 | | | | | | | 2.6 | Formula (3) |
| Synthesis Example 44 | 1-13 | 2-14 | 0.450 | 0.300 | 10 | 18 | 23 | 21 | 19 | 9 | | | | | | 3.5 | Formula (3) |
| Synthesis Example 45 | 1-13 | 2-13 | 0.450 | 0.300 | 15 | 24 | 26 | 21 | 11 | 3 | | | | | | 3.0 | Formula (3) |
| Synthesis Example 46 | 1-14 | 2-14 | 0.450 | 0.300 | 16 | 22 | 27 | 19 | 10 | 6 | | | | | | 3.0 | Formula (3) |
| Synthesis Example 47 | 1-14 | 2-13 | 0.450 | 0.300 | 19 | 26 | 22 | 16 | 12 | 5 | | | | | | 2.9 | Formula (3) |
| Synthesis Example 48 | 1-15 | 2-1 | 0.450 | 0.300 | 11 | 22 | 27 | 20 | 13 | 7 | | | | | | 3.2 | Formula (3) |
| Synthesis Example 49 | 1-15 | 2-14 | 0.450 | 0.300 | 20 | 23 | 22 | 19 | 12 | 4 | | | | | | 2.9 | Formula (3) |
| Synthesis Example 50 | 1-15 | 2-15 | 0.450 | 0.300 | 21 | 27 | 24 | 19 | 8 | 1 | | | | | | 2.7 | Formula (3) |
| Synthesis Example 51 | 1-16 | 2-1 | 0.450 | 0.300 | 17 | 19 | 27 | 24 | 10 | 3 | | | | | | 3.0 | Formula (3) |
| Synthesis Example 52 | 1-16 | 2-14 | 0.450 | 0.300 | 18 | 27 | 21 | 17 | 11 | 6 | | | | | | 2.9 | Formula (3) |
| Synthesis Example 53 | 1-1 | 2-1 | 0.450 | 0.300 | 27 | 30 | 28 | 10 | 5 | | | | | | | 2.4 | Formula (4) |
| Synthesis Example 54 | 1-1 | 2-1 | 0.300 | 0.450 | 18 | 25 | 23 | 15 | 11 | 6 | | | | | | 2.9 | Formula (5) |
| Synthesis Example 55 | 1-1 | 2-1 | 0.300 | 0.450 | 18 | 25 | 23 | 15 | 11 | 6 | | | | | | 2.9 | Formula (6) |
| Synthesis Example 56 | 1-1 | 2-1 | 0.300 | 0.450 | 7 | 16 | 27 | 24 | 17 | 9 | | | | | | 3.6 | Formula (7) |
| Synthesis Example 57 | 1-1 | 2-1 | 0.300 | 0.450 | 6 | 17 | 29 | 24 | 16 | 8 | | | | | | 3.5 | Formula (7) |
| Synthesis Example 58 | 1-1 | 2-1 | 0.300 | 0.450 | 5 | 18 | 33 | 23 | 14 | 7 | | | | | | 3.4 | Formula (8) |

1-1 to 1-16 in the columns “first raw material” in Table 1 and Table 2 are the following compounds.

### “First Raw Materials”

(1-1) Methylhydroquinone

(1-2) Hydroquinone

(1-3) Tetramethylhydroquinone

(1-4) Trimethylhydroquinone

(1-5) 2-(Trifluoromethyl)-1,4-benzenediol

(1-6) Fluorohydroquinone

(1-7) Chlorohydroquinone

(1-8) Bromohydroquinone

(1-9) 2,5-Dihydroxynitrobenzene

(1-10) Tetrafluorohydraquinone

(1-11) Tetrachlorohydroquinone

(1-12) Tetrabromohydroquinone

(1-13) 2,6-Dihydroxynaphthalene

(1-14) 1,5-Dihydroxynaphthalene

(1-15) 4,4′-Dihydroxybiphenyl

(1-16) 3,3′,5,5′-Tetramethylbiphenyl-4,4′-diol 2-1 to 2-15 in the columns “second raw material” in Table 1 and Table 2 are the following compounds.

### “Second Raw Materials”

(2-1) α,α′-p-Dichloroxylene

(2-2) 1,4-Bis(chloromethyl)-2-methylbenzene

(2-3) 3,6-Bis(chloromethyl)durene

(2-4) 1,4-Bis(bromomethyl)-2-fluorobenzene

(2-5) 1,4-Bis(bromomethyl)-2-chlorobenzene

(2-6) 2-Bromo-1,4-bis(bromomethyl)benzene

(2-7) 1,4-Bis(chloromethyl)-2-nitrobenzene

(2-8) 1,4-Bis(bromomethyl)-2,3,5,6-tetrafluorobenzene

(2-9) α,α′,2,3,5,6-Hexachloro-p-xylene

(2-10) 1,2,4,5-Tetrabromo-3,6-bis-bromomethyl-benzene

(2-11) 1,2-Dibromo-3,6-bis(chloromethyl)-4,5-dimethylbenzene

(2-12) 1,4-Bis(bromomethyl)-2,5-dimethylbenzene

(2-13) 4,4′-Bis(chloromethyl)biphenyl

(2-14) 2,6-Bis(bromomethypnaphthalene

(2-15) 1,5-Bis(chloromethyl)naphthalene

For the epoxy resins of Synthesis Example 1 to Synthesis Example 58 obtained as described above, the respective structures were confirmed by a method described below using preparative gel permeation chromatography (GPC) and matrix-assisted laser desorption ionization-time of flight mass spectrometry (MALDI-TOF MS).

First, the epoxy resins of Synthesis Example 1 to Synthesis Example 58 were analyzed, respectively, using preparative gel permeation chromatography (GPC) (manufactured by Shimadzu Corporation), a GPC column (GPCKF-2001 (manufactured by SHODEX) as a column and THF as an eluent. As a result, it was found that the epoxy resins of Synthesis Example 1 to Synthesis Example 57 were all mixtures composed of a plurality of epoxy resins having different molecular weights.

(Measurement of Fractions (mol %) of Individual Components having Different Numbers n of Repeating Units)

Each of the epoxy resins of Synthesis Example 1 to Synthesis Example 58 was separated into components (epoxy resins) having different molecular weights using preparative gel permeation chromatography (GPC). In addition, for the individual components having different molecular weights, the masses were measured in a cation detection mode using matrix-assisted laser desorption ionization-time of flight mass spectrometry (MALDI-TOF MS) (manufactured by JEOL Ltd.), and the value of the peak having the strongest intensity was regarded as the molecular weight. In addition, the measurement results of the obtained molecular weights and the molecular weights of the presumed molecular structures were cross-checked, thereby identifying the epoxy resins of Synthesis Example 1 to Synthesis Example 58, respectively.

The measurement results of the obtained molecular weights and the molecular weights of the presumed molecular structures are shown in Table 3 to Table 7. In addition, the structures of the identified compounds of Synthesis Example 1 to Synthesis Example 58 will be shown below.

TABLE 3

| | Number of repeating | | | | | | | | | | | |
|---|---|---|---|---|---|---|---|---|---|---|---|---|
| Compound | units (n) | 0 | 1 | 2 | 3 | 4 | 5 | 6 | 7 | 8 | 9 | 10 |
| Synthesis | Calculated molecular | 462.54 | 688.87 | 915.20 | 1141.53 | 1367.86 | | | | | | |
| Example 1 | weight value | | | | | | | | | | | |
| | Measured molecular | 461 | 687 | 914 | 1140 | 1366 | | | | | | |
| | weight value | | | | | | | | | | | |
| Synthesis | Calculated molecular | 462.54 | 688.87 | 915.20 | 1141.53 | 1367.86 | 1594.19 | 1820.52 | | | | |
| Example 2 | weight value | | | | | | | | | | | |
| | Measured molecular | 461 | 687 | 914 | 1140 | 1366 | 1593 | 1819 | | | | |
| | weight value | | | | | | | | | | | |
| Synthesis | Calculated molecular | | 688.87 | 915.20 | 1141.53 | 1367.86 | 1594.19 | 1820.52 | 2046.85 | | | |
| Example 3 | weight value | | | | | | | | | | | |
| | Measured molecular | | 687 | 914 | 1140 | 1366 | 1593 | 1819 | 2045 | | | |
| | weight value | | | | | | | | | | | |
| Synthesis | Calculated molecular | | | 915.20 | 1141.53 | 1367.86 | 1594.19 | 1820.52 | 2046.85 | 2273.17 | 2499.50 | 2725.83 |
| Example 4 | weight value | | | | | | | | | | | |
| | Measured molecular | | | 914 | 1140 | 1366 | 1593 | 1819 | 2045 | 2272 | 2498 | 2724 |
| | weight value | | | | | | | | | | | |
| Synthesis | Calculated molecular | | | | | | | 1820.52 | 2046.85 | 2273.17 | 2499.50 | 2725.83 |
| Example 5 | weight value | | | | | | | | | | | |
| | Measured molecular | | | | | | | 1819 | 2045 | 2272 | 2498 | 2724 |
| | weight value | | | | | | | | | | | |
| Synthesis | Calculated molecular | 462.54 | 688.87 | | | | | | | | | |
| Example 6 | weight value | | | | | | | | | | | |
| | Measured molecular | 461 | 687 | | | | | | | | | |
| | weight value | | | | | | | | | | | |
| Synthesis | Calculated molecular | 434.49 | 646.74 | 858.98 | 1071.23 | 1283.48 | 1495.73 | | | | | |
| Example 7 | weight value | | | | | | | | | | | |
| | Measured molecular | 433 | 645 | 857 | 1070 | 1282 | 1494 | | | | | |
| | weight value | | | | | | | | | | | |
| Synthesis | Calculated molecular | 488.52 | 674.79 | 861.07 | 1047.34 | 1233.62 | 1419.89 | 1606.17 | 1792.44 | | | |
| Example 8 | weight value | | | | | | | | | | | |
| | Measured molecular | 487 | 673 | 860 | 1046 | 1232 | 1418 | 1605 | 1791 | | | |
| | weight value | | | | | | | | | | | |
| Synthesis | Calculated molecular | 476.57 | 716.87 | 957.17 | 1197.48 | 1437.78 | 1678.08 | 1918.38 | 2158.68 | | | |
| Example 9 | weight value | | | | | | | | | | | |
| | Measured molecular | 475 | 715 | 956 | 1196 | 1436 | 1677 | 1917 | 2157 | | | |
| | weight value | | | | | | | | | | | |
| Synthesis | Calculated molecular | 546.70 | 815.06 | 1083.42 | 1351.77 | 1620.13 | 1888.48 | 2156.84 | 2425.20 | 2693.55 | | |
| Example 10 | weight value | | | | | | | | | | | |
| | Measured molecular | 545 | 814 | 1082 | 1350 | 1619 | 1887 | 2155 | 2424 | 2692 | | |
| | weight value | | | | | | | | | | | |
| Synthesis | Calculated molecular | 490.60 | 758.95 | 1027.31 | 1295.66 | 1564.02 | 1832.38 | 2100.73 | | | | |
| Example 11 | weight value | | | | | | | | | | | |
| | Measured molecular | 489 | 757 | 1026 | 1294 | 1563 | 1831 | 2099 | | | | |
| | weight value | | | | | | | | | | | |
| Synthesis | Calculated molecular | 602.81 | 927.28 | 1251.74 | 1576.20 | 1900.67 | 2225.13 | 2549.60 | | | | |
| Example 12 | weight value | | | | | | | | | | | |
| | Measured molecular | 601 | 926 | 1250 | 1575 | 1899 | 2224 | 2548 | | | | |
| | weight value | | | | | | | | | | | |

TABLE 4

| Compound | Number of repeating units (n) | 0 | 1 | 2 | 3 | 4 | 5 | 6 | 7 | 8 | 9 | 10 |
|---|---|---|---|---|---|---|---|---|---|---|---|---|
| Synthesis | Calculated molecular weight value | 518.65 | 772.98 | 1027.31 | 1281.64 | 1535.97 | 1790.30 | 2044.62 | | | | |
| Example 13 | Measured molecular weight value | 517 | 771 | 1026 | 1280 | 1534 | 1789 | 2043 | | | | |
| Synthesis | Calculated molecular weight value | 570.48 | 850.73 | 1130.98 | 1411.23 | 1691.47 | 1971.72 | 2251.97 | | | | |
| Example 14 | Measured molecular weight value | 569 | 849 | 1129 | 1410 | 1690 | 1970 | 2250 | | | | |
| Synthesis | Calculated molecular weight value | 470.47 | 700.71 | 930.95 | 1161.18 | 1391.42 | 1621.66 | 1851.90 | | | | |
| Example 15 | Measured molecular weight value | 469 | 699 | 929 | 1160 | 1390 | 1620 | 1850 | | | | |
| Synthesis | Calculated molecular weight value | 503.37 | 750.06 | 996.75 | 1243.44 | 1490.13 | 1736.82 | 1983.51 | 2230.20 | | | |
| Example 16 | Measured molecular weight value | 502 | 749 | 995 | 1242 | 1489 | 1735 | 1982 | 2229 | | | |
| Synthesis | Calculated molecular weight value | 592.28 | 883.42 | 1174.57 | 1465.71 | 1756.86 | 2048.00 | 2339.14 | | | | |
| Example 17 | Measured molecular weight value | 591 | 882 | 1173 | 1464 | 1755 | 2047 | 2338 | | | | |
| Synthesis | Calculated molecular weight value | 524.48 | 781.73 | 1038.97 | 1296.22 | 1553.46 | 1810.71 | 2067.95 | 2325.20 | | | |
| Example 18 | Measured molecular weight value | 523 | 780 | 1037 | 1295 | 1552 | 1809 | 2066 | 2324 | | | |
| Synthesis | Calculated molecular weight value | 584.51 | 878.72 | 1172.92 | 1467.12 | 1761.33 | 2055.53 | 2349.74 | | | | |
| Example 19 | Measured molecular weight value | 583 | 877 | 1171 | 1466 | 1760 | 2054 | 2348 | | | | |
| Synthesis | Calculated molecular weight value | 484.50 | 728.76 | 973.03 | 1217.29 | 1461.56 | 1705.82 | | | | | |
| Example 20 | Measured molecular weight value | 483 | 727 | 972 | 1216 | 1460 | 1704 | | | | | |
| Synthesis | Calculated molecular weight value | 517.40 | 778.12 | 1038.84 | 1299.56 | 1560.28 | 1821.00 | 2081.72 | 2342.44 | | | |
| Example 21 | Measured molecular weight value | 516 | 777 | 1037 | 1298 | 1559 | 1820 | 2080 | 2341 | | | |
| Synthesis | Calculated molecular weight value | 606.31 | 911.48 | 1216.65 | 1521.82 | 1826.99 | 2132.16 | 2437.33 | 2742.50 | 3047.68 | | |
| Example 22 | Measured molecular weight value | 605 | 910 | 1215 | 1520 | 1825 | 2131 | 2436 | 2741 | 3046 | | |
| Synthesis | Calculated molecular weight value | 538.51 | 809.78 | 1081.05 | 1352.33 | 1623.60 | 1894.87 | 2166.14 | | | | |
| Example 23 | Measured molecular weight value | 537 | 808 | 1080 | 1351 | 1622 | 1893 | 2165 | | | | |
| Synthesis | Calculated molecular weight value | 480.53 | 724.80 | 969.06 | 1213.33 | 1457.60 | 1701.86 | 1946.13 | 2190.39 | | | |
| Example 24 | Measured molecular weight value | 479 | 723 | 968 | 1212 | 1456 | 1700 | 1945 | 2189 | | | |

TABLE 5

| Compound | Number of repeating units (n) | 0 | 1 | 2 | 3 | 4 | 5 | 6 | 7 | 8 | 9 | 10 |
|---|---|---|---|---|---|---|---|---|---|---|---|---|
| Synthesis | Calculated molecular weight value | 496.98 | 757.70 | 1018.42 | 1279.14 | 1539.86 | 1800.58 | | | | | |
| Example 25 | Measured molecular weight value | 495 | 756 | 1017 | 1278 | 1538 | 1799 | | | | | |
| Synthesis | Calculated molecular weight value | 541.44 | 846.61 | 1151.78 | 1456.95 | 1762.12 | 2067.29 | | | | | |
| Example 26 | Measured molecular weight value | 540 | 845 | 1150 | 1455 | 1761 | 2066 | | | | | |
| Synthesis | Calculated molecular weight value | 507.54 | 778.81 | 1050.08 | 1321.36 | 1592.63 | 1863.90 | 2135.17 | 2406.44 | 2677.72 | | |
| Example 27 | Measured molecular weight value | 506 | 777 | 1049 | 1320 | 1591 | 1862 | 2134 | 2405 | 2676 | | |
| Synthesis | Calculated molecular weight value | 488.46 | 736.69 | 984.92 | 1233.15 | 1481.38 | 1729.60 | 1977.83 | 2226.06 | 2474.29 | | |
| Example 28 | Measured molecular weight value | 487 | 735 | 983 | 1232 | 1480 | 1728 | 1976 | 2225 | 2473 | | |
| Synthesis | Calculated molecular weight value | 504.91 | 769.59 | 1034.27 | 1298.95 | 1563.63 | 1828.31 | | | | | |
| Example 29 | Measured molecular weight value | 503 | 768 | 1033 | 1297 | 1562 | 1827 | | | | | |
| Synthesis | Calculated molecular weight value | 578.41 | 862.62 | 1146.83 | 1431.04 | 1715.25 | 1999.46 | | | | | |
| Example 30 | Measured molecular weight value | 577 | 861 | 1145 | 1430 | 1714 | 1998 | | | | | |
| Synthesis | Calculated molecular weight value | 710.02 | 1060.04 | 1410.06 | 1760.08 | 2110.1 | 2460.12 | | | | | |
| Example 31 | Measured molecular weight value | 709 | 1059 | 1409 | 1759 | 2109 | 2459 | | | | | |
| Synthesis | Calculated molecular weight value | 1065.66 | 1593.49 | 2121.32 | 2649.15 | 3176.98 | 3704.82 | 4232.65 | | | | |
| Example 32 | Measured molecular weight value | 1064 | 1592 | 2120 | 2648 | 3175 | 3703 | 4231 | | | | |
| Synthesis | Calculated molecular weight value | 506.45 | 790.66 | 1074.87 | 1359.08 | 1643.29 | 1927.50 | 2211.70 | | | | |
| Example 33 | Measured molecular weight value | 505 | 789 | 1073 | 1358 | 1642 | 1926 | 2210 | | | | |
| Synthesis | Calculated molecular weight value | 572.26 | 922.27 | 1272.28 | 1622.29 | 1972.30 | 2322.31 | | | | | |
| Example 34 | Measured molecular weight value | 571 | 921 | 1271 | 1621 | 1971 | 2321 | | | | | |
| Synthesis | Calculated molecular weight value | | 1277.90 | 1805.74 | 2333.57 | 2861.40 | 3389.23 | 3917.06 | 4444.90 | 4972.73 | | |
| Example 35 | Measured molecular weight value | | 1276 | 1804 | 2332 | 2860 | 3388 | 3916 | 4443 | 4971 | | |
| Synthesis | Calculated molecular weight value | 650.37 | 1006.54 | 1362.72 | 1718.89 | 2075.06 | 2431.23 | 2787.40 | | | | |
| Example 36 | Measured molecular weight value | 649 | 1005 | 1361 | 1717 | 2074 | 2430 | 2786 | | | | |

TABLE 6

| Compound | Number of repeating units (n) | 0 | 1 | 2 | 3 | 4 | 5 | 6 | 7 | 8 | 9 | 10 |
|---|---|---|---|---|---|---|---|---|---|---|---|---|
| Synthesis | Calculated molecular weight value | 847.79 | 1335.58 | 1823.37 | 2311.16 | 2798.95 | 3286.74 | | | | | |
| Example 37 | Measured molecular weight value | 846 | 1334 | 1822 | 2310 | 2797 | 3285 | | | | | |
| Synthesis | Calculated molecular weight value | 1381.20 | 2224.66 | 3068.11 | 3911.56 | 4755.01 | 5598.46 | 6441.92 | 7285.37 | | | |
| Example 38 | Measured molecular weight value | 1380 | 2223 | 3067 | 3910 | 4754 | 5597 | 6440 | 7284 | | | |
| Synthesis | Calculated molecular weight value | 648.39 | 1060.51 | 1472.63 | 1884.75 | 2296.87 | 2708.99 | | | | | |
| Example 39 | Measured molecular weight value | 647 | 1059 | 1471 | 1883 | 2295 | 2707 | | | | | |
| Synthesis | Calculated molecular weight value | 490.60 | 744.93 | 999.25 | 1253.58 | 1507.91 | 1762.24 | 2016.57 | 2270.90 | 2525.23 | | |
| Example 40 | Measured molecular weight value | 489 | 743 | 998 | 1252 | 1506 | 1761 | 2015 | 2269 | 2524 | | |
| Synthesis | Calculated molecular weight value | 538.64 | 841.01 | 1143.39 | 1445.76 | 1748.13 | 2050.51 | | | | | |
| Example 41 | Measured molecular weight value | 537 | 840 | 1142 | 1444 | 1747 | 2049 | | | | | |
| Synthesis | Calculated molecular weight value | 484.55 | 746.86 | 1009.16 | 1271.47 | 1533.78 | 1796.09 | 2058.40 | 2320.70 | 2583.01 | | |
| Example 42 | Measured molecular weight value | 483 | 745 | 1008 | 1270 | 1532 | 1795 | 2057 | 2319 | 2582 | | |
| Synthesis | Calculated molecular weight value | 534.61 | 796.92 | 1059.23 | 1321.54 | 1583.85 | | | | | | |
| Example 43 | Measured molecular weight value | 533 | 795 | 1058 | 1320 | 1582 | | | | | | |
| Synthesis | Calculated molecular weight value | 584.67 | 897.04 | 1209.40 | 1521.77 | 1834.14 | 2146.51 | | | | | |
| Example 44 | Measured molecular weight value | 583 | 896 | 1208 | 1520 | 1833 | 2145 | | | | | |
| Synthesis | Calculated molecular weight value | 610.71 | 949.11 | 1287.52 | 1625.92 | 1964.33 | 2302.74 | | | | | |
| Example 45 | Measured molecular weight value | 609 | 948 | 1286 | 1624 | 1963 | 2301 | | | | | |
| Synthesis | Calculated molecular weight value | 584.67 | 897.04 | 1209.40 | 1521.77 | 1834.14 | 2146.51 | | | | | |
| Example 46 | Measured molecular weight value | 583 | 896 | 1208 | 1520 | 1833 | 2145 | | | | | |
| Synthesis | Calculated molecular weight value | 610.71 | 949.11 | 1287.52 | 1625.92 | 1964.33 | 2302.74 | | | | | |
| Example 47 | Measured molecular weight value | 609 | 948 | 1286 | 1624 | 1963 | 2301 | | | | | |

TABLE 7

| Compound | Number of repeating units (n) | 0 | 1 | 2 | 3 | 4 | 5 | 6 | 7 | 8 | 9 | 10 |
|---|---|---|---|---|---|---|---|---|---|---|---|---|
| Synthesis Example 48 | Calculated molecular weight value | 482.53 | 875.03 | 1267.53 | 1660.03 | 2052.52 | 2445.02 | | | | | |
| | Measured molecular weight value | 481 | 874 | 1266 | 1659 | 2051 | 2444 | | | | | |
| Synthesis Example 49 | Calculated molecular weight value | 636.74 | 975.15 | 1313.56 | 1651.96 | 1990.37 | 2328.77 | | | | | |
| | Measured molecular weight value | 635 | 974 | 1312 | 1650 | 1989 | 2327 | | | | | |
| Synthesis Example 50 | Calculated molecular weight value | 636.74 | 975.15 | 1313.56 | 1651.96 | 1990.37 | 2328.77 | | | | | |
| | Measured molecular weight value | 635 | 974 | 1312 | 1650 | 1989 | 2327 | | | | | |
| Synthesis Example 51 | Calculated molecular weight value | 698.90 | 1043.35 | 1387.80 | 1732.25 | 2076.70 | 2421.15 | | | | | |
| | Measured molecular weight value | 697 | 1042 | 1386 | 1731 | 2075 | 2420 | | | | | |
| Synthesis Example 52 | Calculated molecular weight value | 748.96 | 1143.47 | 1537.98 | 1932.49 | 2327.00 | 2721.51 | | | | | |
| | Measured molecular weight value | 747 | 1142 | 1536 | 1931 | 2326 | 2720 | | | | | |
| Synthesis Example 53 | Calculated molecular weight value | 490.60 | 716.87 | 943.15 | 1169.42 | 1395.70 | | | | | | |
| | Measured molecular weight value | 489 | 715 | 942 | 1168 | 1394 | | | | | | |
| Synthesis Example 54 | Calculated molecular weight value | 490.51 | 716.74 | 942.97 | 1169.20 | 1395.43 | 1621.66 | | | | | |
| | Measured molecular weight value | 489 | 715 | 941 | 1168 | 1394 | 1620 | | | | | |
| Synthesis Example 55 | Calculated molecular weight value | 488.54 | 714.82 | 941.09 | 1167.37 | 1393.64 | 1619.92 | | | | | |
| | Measured molecular weight value | 487 | 713 | 940 | 1166 | 1392 | 1618 | | | | | |
| Synthesis Example 56 | Calculated molecular weight value | 572.70 | 798.98 | 1025.25 | 1251.53 | 1477.80 | 1704.08 | | | | | |
| | Measured molecular weight value | 571 | 797 | 1024 | 1250 | 1476 | 1703 | | | | | |
| Synthesis Example 57 | Calculated molecular weight value | 544.65 | 770.92 | 997.20 | 1223.47 | 1449.75 | 1676.02 | | | | | |
| | Measured molecular weight value | 543 | 769 | 996 | 1222 | 1448 | 1675 | | | | | |
| Synthesis Example 58 | Calculated molecular weight value | 490.60 | 716.87 | 943.15 | 1169.42 | 1395.70 | 1621.97 | | | | | |
| | Measured molecular weight value | 489 | 715 | 942 | 1168 | 1394 | 1620 | | | | | |

The compounds of Synthesis Example 1 to Synthesis Example 9 and Synthesis Example 14 to Synthesis Example 29 are indicated by General Formula (C).

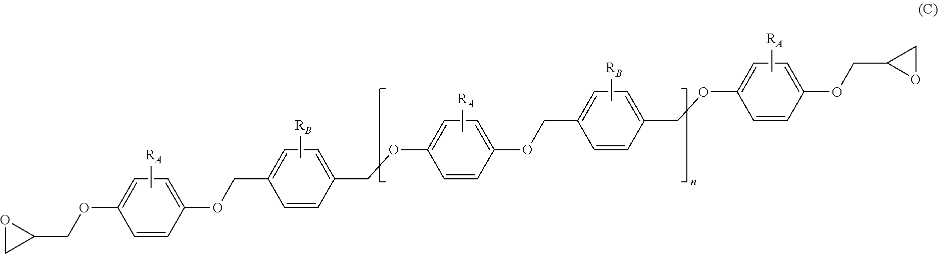

(In Formula (C), R_{A} and R_{B} are a substituent shown in Table 8. Me in Table 8 represents a methyl group. n is a numerical value shown in Table 3 to Table 5.)

TABLE 8

| | Substituent R_{A} | Substituent R_{B} |
|---|---|---|
| Synthesis Example 1 | Me | H |
| Synthesis Example 2 | Me | H |
| Synthesis Example 3 | Me | H |
| Synthesis Example 4 | Me | H |
| Synthesis Example 5 | Me | H |
| Synthesis Example 6 | Me | H |
| Synthesis Example 7 | H | H |
| Synthesis Example 8 | H | Me |
| Synthesis Example 9 | Me | Me |
| Synthesis Example 14 | CF₃ | H |
| Synthesis Example 15 | F | H |
| Synthesis Example 16 | Cl | H |
| Synthesis Example 17 | Br | H |
| Synthesis Example 18 | NO₂ | H |
| Synthesis Example 19 | CF₃ | Me |
| Synthesis Example 20 | F | Me |
| Synthesis Example 21 | Cl | Me |
| Synthesis Example 22 | Br | Me |
| Synthesis Example 23 | NO₂ | Me |
| Synthesis Example 24 | Me | F |
| Synthesis Example 25 | Me | Cl |
| Synthesis Example 26 | Me | Br |
| Synthesis Example 27 | Me | NO₂ |
| Synthesis Example 28 | F | F |
| Synthesis Example 29 | F | Cl |

The compounds of Synthesis Example 10 to Synthesis Example 12 and Synthesis Example 30 to Synthesis Example 38 are indicated by General Formula (D).

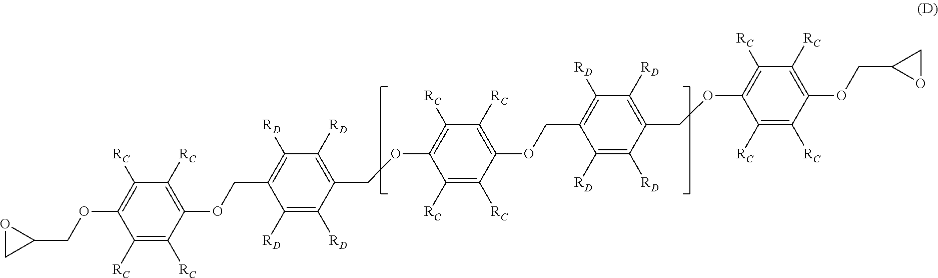

(In Formula (D), R_{C} and R_{D} are a substituent shown in Table 9. Me in Table 9 represents a methyl group. n is a numerical value shown in Table 3, Table 5 and Table 6.)

TABLE 9

| | Substituent R_{C} | Substituent R_{D} |
|---|---|---|
| Synthesis Example 10 | Me | H |
| Synthesis Example 11 | H | Me |
| Synthesis Example 12 | Me | Me |
| Synthesis Example 30 | F | H |
| Synthesis Example 31 | Cl | H |
| Synthesis Example 32 | Br | H |
| Synthesis Example 33 | H | F |
| Synthesis Example 34 | H | Cl |
| Synthesis Example 35 | H | Br |
| Synthesis Example 36 | F | F |
| Synthesis Example 37 | Cl | Cl |
| Synthesis Example 38 | Br | Br |

The compound of Synthesis Example 13 is indicated by General Formula (E).

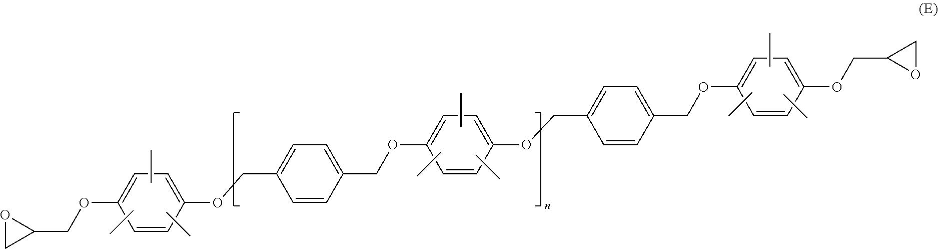

(In Formula (E), n is the numerical value shown in Table 4.)

The compound of Synthesis Example 39 is indicated by General Formula (F).

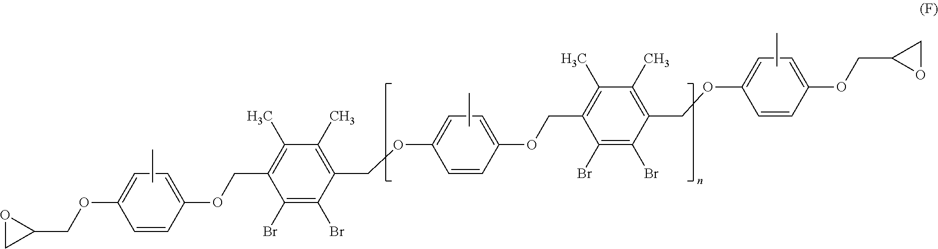

(In Formula (F), n is the numerical value shown in Table 6.)

The compound of Synthesis Example 40 is indicated by General Formula (G).

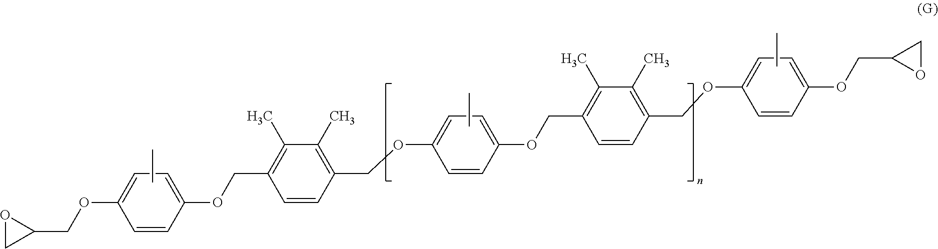

(In Formula (G), n is the numerical value shown in Table 6.)

The compounds of Synthesis Example 43 to Synthesis Example 52 are indicated by General Formula (1) shown above (in Formula (1), Ar₁ an Ar₂ are each an aromatic cyclic group shown in Table 10 or Table 11, and Ar₃ is identical to Ar₁. Z is an end group having an epoxy group that is indicated by Formula (3) shown above. n is a numerical value shown in Table 6 and Table 7.).

TABLE 10

| | A₁ | Ar₂ |
|---|---|---|
| SYSTHESIS EXAMPLE 41 | 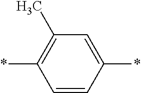 [SMILES: *c1ccc(*)c(C)c1] | 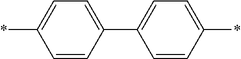 [SMILES: *c1ccc(-c2ccc(*)cc2)cc1] |
| SYSTHESIS EXAMPLE 42 | 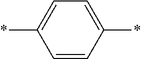 [SMILES: *c1ccc(*)cc1] | 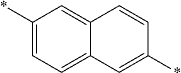 [SMILES: *c1ccc2cc(*)ccc2c1] |
| SYSTHESIS EXAMPLE 43 | 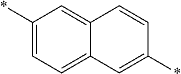 [SMILES: *c1ccc2cc(*)ccc2c1] | 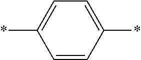 [SMILES: *c1ccc(*)cc1] |
| SYSTHESIS EXAMPLE 44 | 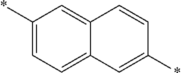 [SMILES: *c1ccc2cc(*)ccc2c1] | 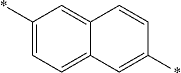 [SMILES: *c1ccc2cc(*)ccc2c1] |
| SYSTHESIS EXAMPLE 45 | 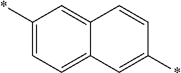 [SMILES: *c1ccc2cc(*)ccc2c1] | 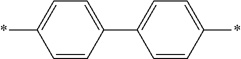 [SMILES: *c1ccc(-c2ccc(*)cc2)cc1] |
| SYSTHESIS EXAMPLE 46 | 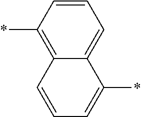 [SMILES: *c1cccc2c(*)cccc12] | 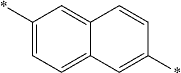 [SMILES: *c1ccc2cc(*)ccc2c1] |

TABLE 11

| | A₁ | Ar₂ |
|---|---|---|
| SYTHESIS EXAMPLE 47 | 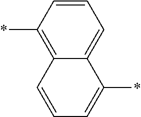 [SMILES: *c1cccc2c(*)cccc12] | 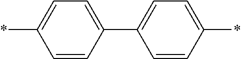 [SMILES: *c1ccc(-c2ccc(*)cc2)cc1] |
| SYSTHESIS EXAMPLE 48 | 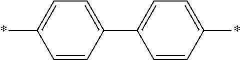 [SMILES: *c1ccc(-c2ccc(*)cc2)cc1] | 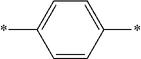 [SMILES: *c1ccc(*)cc1] |
| SYSTHESIS EXAMPLE 49 | 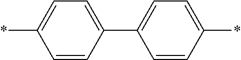 [SMILES: *c1ccc(-c2ccc(*)cc2)cc1] | 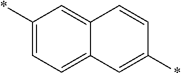 [SMILES: *c1ccc2cc(*)ccc2c1] |
| SYSTHESIS EXAMPLE 50 | 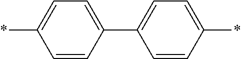 [SMILES: *c1ccc(-c2ccc(*)cc2)cc1] | 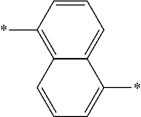 [SMILES: *c1cccc2c(*)cccc12] |
| SYSTHESIS EXAMPLE 51 | 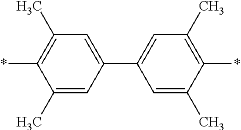 [SMILES: *c1c(C)cc(-c2cc(C)c(*)c(C)c2)cc1C] | 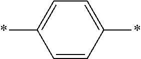 [SMILES: *c1ccc(*)cc1] |
| SYSTHESIS EXAMPLE 52 | 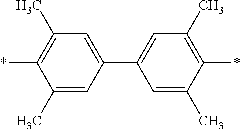 [SMILES: *c1c(C)cc(-c2cc(C)c(*)c(C)c2)cc1C] | 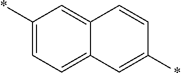 [SMILES: *c1ccc2cc(*)ccc2c1] |

The compound of Synthesis Example 53 is indicated by General Formula (H).

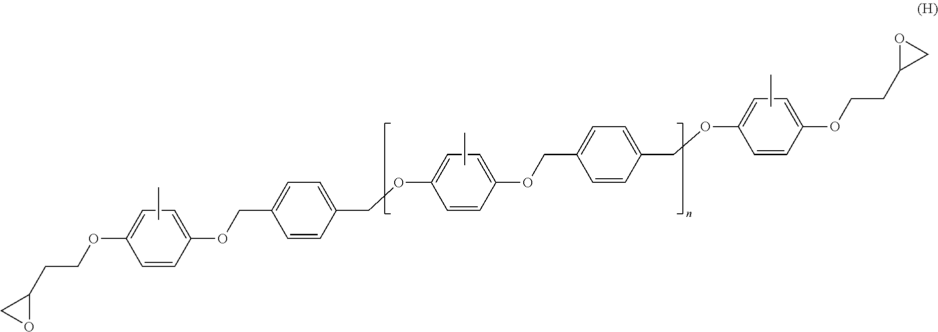

(In Formula (H), n is the numerical value shown in Table 7.)

The compound of Synthesis Example 54 is indicated by General Formula (I) below (in Formula (I), n is the numerical value shown in Table 7. A is O.).

The compound of Synthesis Example 55 is indicated by General Formula (I) below (in Formula (I), n is the numerical value shown in Table 7. A is NH.).

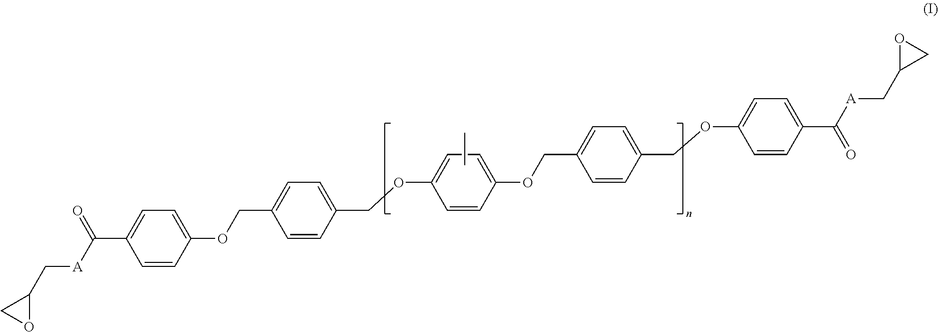

The compound of Synthesis Example 56 is indicated by General Formula (J) below (in Formula (J), n is the numerical value shown in Table 7. R is —CH3.).

The compound of Synthesis Example 57 is indicated by General Formula (J) below (in Formula (J), n is the numerical value shown in Table 7. R is —H.).

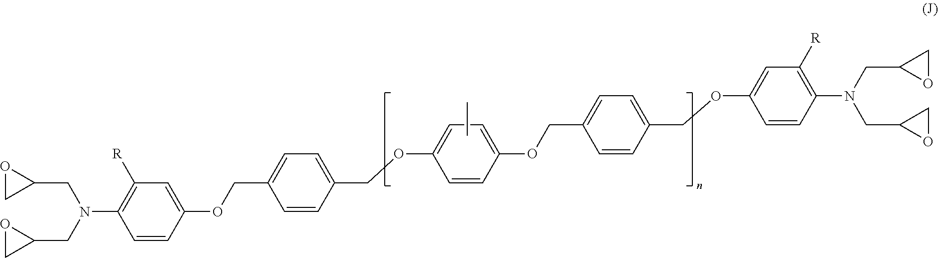

The compound of Synthesis Example 58 is indicated by General Formula (K).

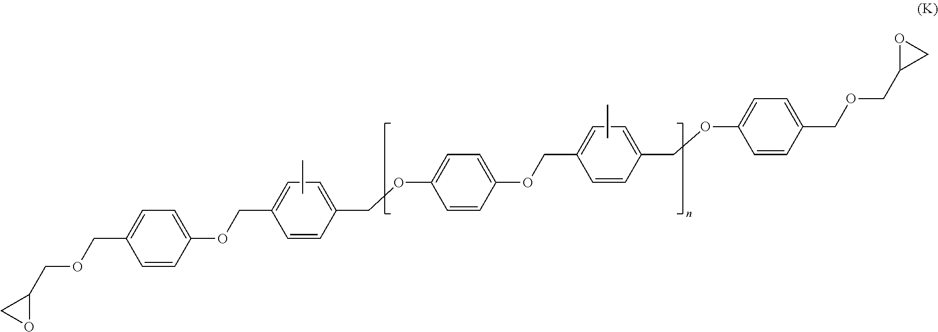

(In Formula (K), n is a numerical value shown in Table 6.)

As a result of identifying the compounds of Synthesis Example 1 to Synthesis Example 58, as described above, the epoxy resins of Synthesis Example 1 to Synthesis Example 58 were compounds including the first aromatic cyclic units each composed of a first aromatic cyclic group and two ether oxygens bonding to the first aromatic cyclic group, the second aromatic cyclic units each composed of a second aromatic cyclic group and two methylene groups bonding to the second aromatic cyclic group and the third aromatic cyclic units each composed of a third aromatic cyclic group and an end group having an epoxy group that bonds to the third aromatic cyclic group, in which a skeleton in which the first aromatic cyclic units and the second aromatic cyclic units were alternately disposed was included, and the first aromatic cyclic units were disposed at both ends of the skeleton and bonded to the third aromatic cyclic groups with the methylene groups or the second aromatic cyclic units were disposed at both ends of the skeleton and bonded to the thiskeleton and bonded to the third aromatic cyclic groups with the ether oxygens.

In addition, from the measurement results of the molecular weights, the average polymerization degrees, which are the average value of the numbers of the repeating units, of the epoxy resins of Synthesis Example 1 to Synthesis Example 58 were calculated.

In addition, solutions containing the components (epoxy resins) having different molecular weights, which had been separated with GPC, respectively, were dried, the masses thereof were measured, and the fractions (mol %) of the individual components that were contained in the epoxy resins of Synthesis Example 1 to Synthesis Example 58 were calculated.

Table 1 and Table 2 show the fractions of the individual components (epoxy resins) having different number of the repeating units that were contained in the epoxy resins of Synthesis Example 1 to Synthesis Example 58 (the fractions (mol %) of the individual components having different “numbers n of the repeating units”) and the average polymerization degrees.

### <Production of Resin Composition>

### Examples 1 to 15, 18 to 22, 25 to 29 and 32 to 83

An epoxy resin shown in Table 12 to Table 14, a curing agent shown in Table 12 to Table 14 and a curing accelerator shown in Table 12 to Table 14 were mixed in fractions shown in Table 12 to Table 14, respectively, thereby obtaining resin compositions of Examples 1 to 15, 18 to 22, 25 to 29 and 32 to 83.

2E4MZ, which is a resin curing agent, shown in Table 12 to Table 14 is 2-ethyl-4-methylimidazole.

### Examples 16, 23 and 30

As an epoxy resin, an epoxy resin obtained by mixing the epoxy resin of Synthesis Example 5 and the epoxy resin of Synthesis Example 6 in fractions of 1:1 in terms of the mass ratio was used, a curing agent shown in Table 12 and a curing accelerator shown in Table 12 were mixed in fractions shown in Table 12, respectively, thereby obtaining the resin compositions of Examples 16, 23 and 30.

### Examples 17, 24 and 31

As an epoxy resin, an epoxy resin obtained by mixing the epoxy resins of Synthesis Examples 1, 3, 4 and 5 in fractions of 1:1:1:1 in terms of the mass ratio was used, a curing agent shown in Table 12 and Table 13 and a curing accelerator shown in Table 12 and Table 13 were mixed in fractions shown in Table 12 and Table 13, respectively, thereby obtaining resin compositions of Examples 17, 24 and 31.

TABLE 12

| | | | | Epoxy | Curing | Curing | Thermal |
|---|---|---|---|---|---|---|---|
| Resin | | | Curing | resin | agent | accelerator | conductivity |
| composition | Epoxy resin | Curing agent | accelerator | (mass %) | (mass %) | (mass %) | W/(m · K) |
| Example 1 | Synthesis Example 1 | p-Phenylenediamine | 2E4MZ | 90 | 7 | 3 | 0.5 |
| Example 2 | Synthesis Example 1 | 1,5-Diaminonaphthalene | 2E4MZ | 90 | 7 | 3 | 0.6 |
| Example 3 | Synthesis Example 1 | Hydroquinone | 2E4MZ | 90 | 7 | 3 | 0.5 |
| Example 4 | Synthesis Example 1 | 2,6-Dihydroxynaphthalene | 2E4MZ | 90 | 7 | 3 | 0.6 |
| Example 5 | Synthesis Example 1 | Phloroglucinol | 2E4MZ | 90 | 7 | 3 | 0.6 |
| Example 6 | Synthesis Example 1 | 4-Hydroxybenzoic acid | 2E4MZ | 90 | 7 | 3 | 0.5 |
| Example 7 | Synthesis Example 1 | 6-Hydroxy-2-naphthoic acid | 2E4MZ | 90 | 7 | 3 | 0.5 |
| Example 8 | Synthesis Example 1 | 4-Aminobenzoic acid | 2E4MZ | 90 | 7 | 3 | 0.7 |
| Example 9 | Synthesis Example 1 | Phenolic resin | 2E4MZ | 90 | 7 | 3 | 0.5 |
| Example 10 | Synthesis Example 1 | Polyamideamine | 2E4MZ | 90 | 7 | 3 | 0.5 |
| Example 11 | Synthesis Example 2 | p-Phenylenediamine | 2E4MZ | 90 | 7 | 3 | 0.6 |
| Example 12 | Synthesis Example 3 | p-Phenylenediamine | 2E4MZ | 90 | 7 | 3 | 0.7 |
| Example 13 | Synthesis Example 4 | p-Phenylenediamine | 2E4MZ | 90 | 7 | 3 | 0.6 |
| Example 14 | Synthesis Example 5 | p-Phenylenediamine | 2E4MZ | 90 | 7 | 3 | 0.5 |
| Example 15 | Synthesis Example 6 | p-Phenylenediamine | 2E4MZ | 90 | 7 | 3 | 0.5 |
| Example 16 | Synthesis Example 5, 6 | p-Phenylenediamine | 2E4MZ | 90 | 7 | 3 | 0.5 |
| Example 17 | Synthesis Example | p-Phenylenediamine | 2E4MZ | 90 | 7 | 3 | 0.5 |
| | 1, 3, 4, 5 | | | | | | |
| Example 18 | Synthesis Example 2 | 4-Aminobenzoic acid | 2E4MZ | 90 | 7 | 3 | 0.7 |
| Example 19 | Synthesis Example 3 | 4-Aminobenzoic acid | 2E4MZ | 90 | 7 | 3 | 0.8 |
| Example 20 | Synthesis Example 4 | 4-Aminobenzoic acid | 2E4MZ | 90 | 7 | 3 | 0.6 |
| Example 21 | Synthesis Example 5 | 4-Aminobenzoic acid | 2E4MZ | 90 | 7 | 3 | 0.5 |
| Example 22 | Synthesis Example 6 | 4-Aminobenzoic acid | 2E4MZ | 90 | 7 | 3 | 0.5 |
| Example 23 | Synthesis Example 5, 6 | 4-Aminobenzoic acid | 2E4MZ | 90 | 7 | 3 | 0.5 |
| Example 24 | Synthesis Example | 4-Aminobenzoic acid | 2E4MZ | 90 | 7 | 3 | 0.6 |
| | 1, 3, 4, 5 | | | | | | |
| Example 25 | Synthesis Example 2 | Phenolic resin | 2E4MZ | 90 | 7 | 3 | 0.5 |
| Example 26 | Synthesis Example 3 | Phenolic resin | 2E4MZ | 90 | 7 | 3 | 0.7 |
| Example 27 | Synthesis Example 4 | Phenolic resin | 2E4MZ | 90 | 7 | 3 | 0.6 |
| Example 28 | Synthesis Example 5 | Phenolic resin | 2E4MZ | 90 | 7 | 3 | 0.5 |
| Example 29 | Synthesis Example 6 | Phenolic resin | 2E4MZ | 90 | 7 | 3 | 0.5 |
| Example 30 | Synthesis Example 5, 6 | Phenolic resin | 2E4MZ | 90 | 7 | 3 | 0.5 |

TABLE 13

| | | | | Epoxy | Curing | Curing | Thermal |
|---|---|---|---|---|---|---|---|
| Resin | | | Curing | resin | agent | accelerator | conductivity |
| composition | Epoxy resin | Curing agent | accelerator | (mass %) | (mass %) | (mass %) | W/(m · K) |
| Example 31 | Synthesis Example | Phenolic resin | 2E4MZ | 90 | 7 | 3 | 0.5 |
| | 1, 3, 4, 5 | | | | | | |
| Example 32 | Synthesis Example 7 | p-Phenylenediamine | 2E4MZ | 90 | 7 | 3 | 0.6 |
| Example 33 | Synthesis Example 8 | p-Phenylenediamine | 2E4MZ | 90 | 7 | 3 | 0.6 |
| Example 34 | Synthesis Example 9 | p-Phenylenediamine | 2E4MZ | 90 | 7 | 3 | 0.6 |
| Example 35 | Synthesis Example 10 | p-Phenylenediamine | 2E4MZ | 90 | 7 | 3 | 0.6 |
| Example 36 | Synthesis Example 11 | p-Phenylenediamine | 2E4MZ | 90 | 7 | 3 | 0.6 |
| Example 37 | Synthesis Example 12 | p-Phenylenediamine | 2E4MZ | 90 | 7 | 3 | 0.5 |
| Example 38 | Synthesis Example 13 | p-Phenylenediamine | 2E4MZ | 90 | 7 | 3 | 0.5 |
| Example 39 | Synthesis Example 14 | p-Phenylenediamine | 2E4MZ | 90 | 7 | 3 | 0.6 |
| Example 40 | Synthesis Example 15 | p-Phenylenediamine | 2E4MZ | 90 | 7 | 3 | 0.6 |
| Example 41 | Synthesis Example 16 | p-Phenylenediamine | 2E4MZ | 90 | 7 | 3 | 0.6 |
| Example 42 | Synthesis Example 17 | p-Phenylenediamine | 2E4MZ | 90 | 7 | 3 | 0.5 |
| Example 43 | Synthesis Example 18 | p-Phenylenediamine | 2E4MZ | 90 | 7 | 3 | 0.5 |
| Example 44 | Synthesis Example 19 | p-Phenylenediamine | 2E4MZ | 90 | 7 | 3 | 0.7 |
| Example 45 | Synthesis Example 20 | p-Phenylenediamine | 2E4MZ | 90 | 7 | 3 | 0.5 |
| Example 46 | Synthesis Example 21 | p-Phenylenediamine | 2E4MZ | 90 | 7 | 3 | 0.5 |
| Example 47 | Synthesis Example 22 | p-Phenylenediamine | 2E4MZ | 90 | 7 | 3 | 0.5 |
| Example 48 | Synthesis Example 23 | p-Phenylenediamine | 2E4MZ | 90 | 7 | 3 | 0.5 |
| Example 49 | Synthesis Example 24 | p-Phenylenediamine | 2E4MZ | 90 | 7 | 3 | 0.7 |
| Example 50 | Synthesis Example 25 | p-Phenylenediamine | 2E4MZ | 90 | 7 | 3 | 0.5 |
| Example 51 | Synthesis Example 26 | p-Phenylenediamine | 2E4MZ | 90 | 7 | 3 | 0.6 |
| Example 52 | Synthesis Example 27 | p-Phenylenediamine | 2E4MZ | 90 | 7 | 3 | 0.7 |
| Example 53 | Synthesis Example 28 | p-Phenylenediamine | 2E4MZ | 90 | 7 | 3 | 0.6 |
| Example 54 | Synthesis Example 29 | p-Phenylenediamine | 2E4MZ | 90 | 7 | 3 | 0.5 |
| Example 55 | Synthesis Example 30 | p-Phenylenediamine | 2E4MZ | 90 | 7 | 3 | 0.7 |
| Example 56 | Synthesis Example 31 | p-Phenylenediamine | 2E4MZ | 90 | 7 | 3 | 0.7 |
| Example 57 | Synthesis Example 32 | p-Phenylenediamine | 2E4MZ | 90 | 7 | 3 | 0.5 |
| Example 58 | Synthesis Example 33 | p-Phenylenediamine | 2E4MZ | 90 | 7 | 3 | 0.5 |
| Example 59 | Synthesis Example 34 | p-Phenylenediamine | 2E4MZ | 90 | 7 | 3 | 0.6 |
| Example 60 | Synthesis Example 35 | p-Phenylenediamine | 2E4MZ | 90 | 7 | 3 | 0.7 |

TABLE 14

| | | | | Epoxy | Curing | Curing | Thermal |
|---|---|---|---|---|---|---|---|
| Resin | | | Curing | resin | agent | accelerator | conductivity |
| composition | Epoxy resin | Curing agent | accelerator | (mass %) | (mass %) | (mass %) | W/(m · K) |
| Example 61 | Synthesis Example 36 | p-Phenylenediamine | 2E4MZ | 90 | 7 | 3 | 0.7 |
| Example 62 | Synthesis Example 37 | p-Phenylenediamine | 2E4MZ | 90 | 7 | 3 | 0.5 |
| Example 63 | Synthesis Example 38 | p-Phenylenediamine | 2E4MZ | 90 | 7 | 3 | 0.7 |
| Example 64 | Synthesis Example 39 | p-Phenylenediamine | 2E4MZ | 90 | 7 | 3 | 0.5 |
| Example 65 | Synthesis Example 40 | p-Phenylenediamine | 2E4MZ | 90 | 7 | 3 | 0.6 |
| Example 66 | Synthesis Example 41 | p-Phenylenediamine | 2E4MZ | 90 | 7 | 3 | 0.6 |
| Example 67 | Synthesis Example 42 | p-Phenylenediamine | 2E4MZ | 90 | 7 | 3 | 0.5 |
| Example 68 | Synthesis Example 43 | p-Phenylenediamine | 2E4MZ | 90 | 7 | 3 | 0.7 |
| Example 69 | Synthesis Example 44 | p-Phenylenediamine | 2E4MZ | 90 | 7 | 3 | 0.6 |
| Example 70 | Synthesis Example 45 | p-Phenylenediamine | 2E4MZ | 90 | 7 | 3 | 0.5 |
| Example 71 | Synthesis Example 46 | p-Phenylenediamine | 2E4MZ | 90 | 7 | 3 | 0.6 |
| Example 72 | Synthesis Example 47 | p-Phenylenediamine | 2E4MZ | 90 | 7 | 3 | 0.6 |
| Example 73 | Synthesis Example 48 | p-Phenylenediamine | 2E4MZ | 90 | 7 | 3 | 0.7 |
| Example 74 | Synthesis Example 49 | p-Phenylenediamine | 2E4MZ | 90 | 7 | 3 | 0.6 |
| Example 75 | Synthesis Example 50 | p-Phenylenediamine | 2E4MZ | 90 | 7 | 3 | 0.5 |
| Example 76 | Synthesis Example 51 | p-Phenylenediamine | 2E4MZ | 90 | 7 | 3 | 0.5 |
| Example 77 | Synthesis Example 52 | p-Phenylenediamine | 2E4MZ | 90 | 7 | 3 | 0.5 |
| Example 78 | Synthesis Example 53 | p-Phenylenediamine | 2E4MZ | 90 | 7 | 3 | 0.5 |
| Example 79 | Synthesis Example 54 | p-Phenylenediamine | 2E4MZ | 90 | 7 | 3 | 0.7 |
| Example 80 | Synthesis Example 55 | p-Phenylenediamine | 2E4MZ | 90 | 7 | 3 | 0.7 |
| Example 81 | Synthesis Example 56 | p-Phenylenediamine | 2E4MZ | 90 | 7 | 3 | 0.6 |
| Example 82 | Synthesis Example 57 | p-Phenylenediamine | 2E4MZ | 90 | 7 | 3 | 0.6 |
| Example 83 | Synthesis Example 58 | p-Phenylenediamine | 2E4MZ | 90 | 7 | 3 | 0.6 |

For each of the resin compositions of Examples 1 to 83 obtained as described above, the thermal conductivity was obtained by a method described below. The results are shown in Table 12 to Table 14.

### (Measurement of Thermal Conductivity)

The density, specific heat and thermal diffusivity of the resin composition were measured by methods described below, respectively, and multiplied by one another, thereby obtaining the thermal conductivity.

The density was obtained using the Archimedes method.

The specific heat was obtained using a differential scanning calorimeter (DSC) (manufactured by Hitachi High-Tech Science Corporation).

The thermal diffusivity was obtained using a thermal diffusivity measurement system by the Xe flash method (Advance Riko, Inc.).

A sample for measurement produced by a method described below was used for the measurement of the thermal diffusivity. That is, the resin composition was rapidly melted and mixed in an aluminum cup at a temperature of 180° C. and cooled to room temperature. After that, the uncured resin composition was heated at 100° C. for one hour, at 150° C. for one hour and at 180° C. for 30 minutes in this order and cured. The obtained resin cured product was processed into a cylindrical shape that was 10 mm in diameter and 0.5 mm in thickness and used as a sample for measurement.

As shown in Table 12 to Table 14, all of the cured products of the resin compositions of Examples 1 to 83 had a thermal conductivity of 0.5 W/(m·K) or higher, and the cured products had a high thermal conductivity.

### INDUSTRIAL APPLICABILITY

The present disclosure provides an epoxy resin from which a cured product having a high thermal conductivity can be obtained.

### BRIEF DESCRIPTION OF THE REFERENCE SYMBOLS

10 Resin substrate

12 Resin sheet

20 Cured product

22 Resin component

30 Core

50 Multilayer substrate

1. An epoxy resin comprising,
end groups each having an epoxy group that are disposed at both ends respectively, and
between the end groups, either or both of:
a first structure in which an aromatic cyclic group, an ether oxygen, a methylene group, an aromatic cyclic group, a methylene group, an ether oxygen and an aromatic cyclic group are bonded together in this order; and
a second structure in which an aromatic cyclic group, a methylene group, an ether oxygen, an aromatic cyclic group, an ether oxygen, a methylene group and an aromatic cyclic group are bonded together in this order.

2. The epoxy resin according to claim 1, comprising:
a first aromatic cyclic unit composed of a first aromatic cyclic group and two ether oxygens bonding to the first aromatic cyclic group;
a second aromatic cyclic unit composed of a second aromatic cyclic group and two methylene groups bonding to the second aromatic cyclic group; and
a third aromatic cyclic unit composed of a third aromatic cyclic group and an end group having an epoxy group that bonds to the third aromatic cyclic group,
wherein the epoxy resin comprises a skeleton in which the first aromatic cyclic units and the second aromatic cyclic units are alternately disposed, and
the first aromatic cyclic units are disposed at both ends of the skeleton and bonded to the third aromatic cyclic groups via methylene groups or
the second aromatic cyclic units are disposed at both ends of the skeleton and bonded to the third aromatic cyclic groups via ether oxygens.

3. The epoxy resin according to claim 1 that is represented by General Formula (1) below or General Formula (2) below, 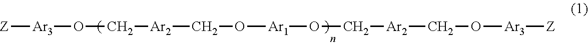
(in Formula (1), Ar₁ each independently represents a first aromatic cyclic group that may have a substituent, Ar₂ each independently represents a second aromatic cyclic group that may have a substituent, and Ar₃ each independently represents a third aromatic cyclic group that may have a substituent; Z each independently represents an end group having an epoxy group; and n is an integer of 0 or larger,) 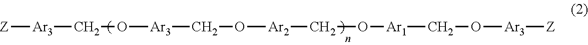
(in Formula (2), Ar₁ each independently represents a first aromatic cyclic group that may have a substituent, Ar₂ each independently represents a second aromatic cyclic group that may have a substituent, and Ar₃ each independently represents a third aromatic cyclic group that may have a substituent; Z each independently represents an end group having an epoxy group; and n is an integer of 0 or larger).

4. The epoxy resin according to claim 2,
wherein one or more of the first aromatic cyclic group, the second aromatic cyclic group and the third aromatic cyclic group are a para-phenylene group that may have a substituent.

5. The epoxy resin according to claim 2,
wherein the first aromatic cyclic group and the third aromatic cyclic group are identical to each other, and
the second aromatic cyclic group is a para-phenylene group.

6. The epoxy resin according to claim 1 that is represented by General Formula (9) below, 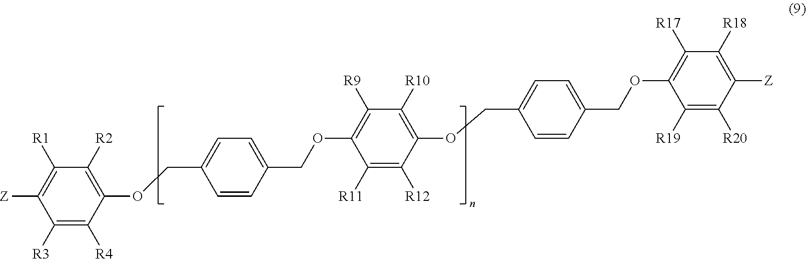
(in Formula (9), R1 to R4, R9 to R12 and R17 to R20 are each independently any one selected from the group consisting of hydrogen, a methyl group, a trifluoromethyl group, a halogen group and a nitro group, Z each independently represents an end group having an epoxy group and n is an integer of 0 or larger).

7. The epoxy resin according to claim 6,
wherein any one of the R1 to the R4 is a methyl group and others are hydrogen, any one of the R9 to the R12 is a methyl group and the others are hydrogen, and any one of the R17 to the R20 is a methyl group and others are hydrogen.

8. The epoxy resin according to claim 3,
wherein the n is an integer of 0 to 10.

9. The epoxy resin according to claim 1,
wherein the end group having an epoxy group is a group in which an epoxy group is bonded to a linking group having one or more of a methylene group, an ether bond, an ester bond, a ketone group and an amide bond.

10. The epoxy resin according to claim 1,
wherein the end group having an epoxy group is any one of Formulae (3) to (8) below,

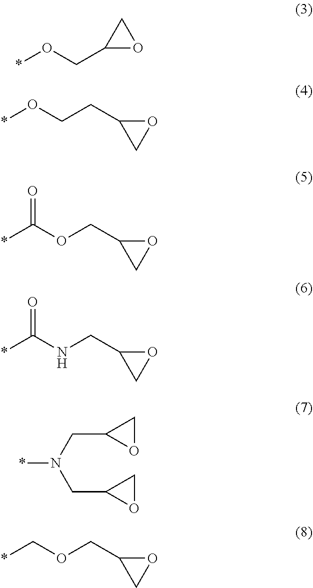

11. A resin composition comprising:
the epoxy resin according to claim 1.

12. A resin sheet that is obtained by forming the resin composition according to claim 11.

13. A resin cured product comprising:
a cured product of the resin composition according to claim 11.

14. A resin substrate comprising:
a cured product of the resin composition according to claim 11.

15. A multilayer substrate,
wherein a plurality of resin substrates is laminated, and at least one of the plurality of resin substrates includes a cured product of the resin composition according to claim 11.

16. The epoxy resin according to claim 6, wherein the n is an integer of 0 to 10.
